(19) United States
(12) Patent Application Publication
(10) Pub. No.: US 2026/0341352 A1
(43) Pub. Date: Oct. 29, 2026

(54) RESISTIVE MEMORY ARRAY USING NEGATIVE GATE VOLTAGE DURING SENSING AND METHODS FOR OPERATING THE SAME

(71) Applicant: Taiwan Semiconductor Manufacturing Company Limited, Hsinchu (TW)

(72) Inventors: Chih-Yang Chang, Yuanlin Township (TW); Wen-Ting Chu, Kaohsiung City (TW)

(21) Appl. No.: 19/188,096

(22) Filed: Apr. 24, 2025

(51) Int. Cl. G11C 13/00

(52) U.S. Cl. CPC G11C 13/0033; G11C 13/0026; G11C 13/0028; G11C 13/004

(57) ABSTRACT

A resistive memory device includes a primary memory array, a complementary memory array, and sense amplifiers. Each sense amplifier has input nodes connected to a primary bit line and a complementary bit line. A control circuit performs read operations by electrically biasing a selected word line with a word line activation voltage and all unselected word lines in the primary memory array with a leakage-current suppression voltage having an opposite polarity of the word line activation voltage. The leakage-current suppression voltage suppress leakage current through unselected primary memory cells. The resistive state of a selected memory cell is sensed by generating an output voltage from a selected sense amplifier.

### BACKGROUND

Resistive random access memory (RRAM) refers to a type of non-volatile memory that operates by changing the resistance across a dielectric solid-state material. In RRAM devices, the resistance of the memory element may be electrically switched between high and low resistance states, representing different logic values. As the size of a RRAM cell decreases, the read window - defined as the difference between the bit line currents for different resistive states during measurement at an input node of a sense amplifier - may continue to shrink. This reduction in the read window makes reliable sensing of the resistance states of a RRAM cell challenging. Further, bit line leakage currents increase with the reduction in the RRAM cell size. This problem is exacerbated in designs with long bit lines each connected to a respective column of 1,000 resistive memory cells or more. The cumulative leakage through unselected resistive memory cells connected to a bit line interferes with the sensing of the resistive state of the selected resistive memory cell, and increases the read error rates.

### BRIEF DESCRIPTION OF FIGURES

Aspects of the present disclosure are best understood from the following detailed description when read with the accompanying figures. The various features of elements may not be drawn to scale, and some elements may be omitted in the drawings for clarity.

FIG. 1 is a vertical cross-sectional view of an exemplary structure including a resistive memory device according to an embodiment of the present disclosure.

FIG. 2 is a schematic circuit diagram of a resistive memory array and a subset of peripheral circuits during a reset operation on an i-th row j-th column resistive memory cell according to an embodiment of the present disclosure.

FIG. 3 is a schematic circuit diagram of the resistive memory array and the subset of peripheral circuits during a set operation on an i-th row j-th column resistive memory cell according to an embodiment of the present disclosure.

FIG. 4A is a schematic circuit diagram of a first exemplary resistive memory device of the present disclosure according to an embodiment of the present disclosure.

FIG. 4B is a schematic circuit diagram of a memory array and peripheral circuits within the first exemplary resistive memory device of FIG. 4A during a read operation on an i-th row j-th column resistive memory cell according to an embodiment of the present disclosure.

FIG. 4C is a schematic circuit diagram of a memory array and peripheral circuits within the first exemplary resistive memory device of FIG. 4A during an alternative read operation on an i-th row j-th column resistive memory cell according to an embodiment of the present disclosure.

FIG. 5A is a schematic circuit diagram of a second exemplary resistive memory device of the present disclosure according to an embodiment of the present disclosure.

FIG. 5B is a schematic circuit diagram of a primary memory array and first peripheral circuits within the second exemplary resistive memory device of FIG. 5A during a read operation according to an embodiment of the present disclosure.

FIG. 5C is a schematic circuit diagram of a complementary memory array and second peripheral circuits within the second exemplary resistive memory device of FIG. 5A during the read operation of FIG. 5B according to an embodiment of the present disclosure.

FIG. 5D is a schematic circuit diagram of a primary memory array and first peripheral circuits within the second exemplary resistive memory device of FIG. 5A during an alternative read operation according to an embodiment of the present disclosure.

FIG. 5E is a schematic circuit diagram of a complementary memory array and second peripheral circuits within the second exemplary resistive memory device of FIG. 5A during the alternative read operation of FIG. 5D according to an embodiment of the present disclosure.

FIG. 6 is a graph showing the probability distribution of bit line leakage current for a first operational mode in which 0 V is applied to unselected word lines, and for a second operational mode in which -0.2 V is applied to the unselected word lines during a read operation on a resistive memory array.

FIG. 7 is a graph showing the probability distribution of bit line leakage current mismatch between a pair of a primary bit line and a complementary bit line for a first operational mode in which 0 V is applied to unselected word lines, and for a second operational mode in which -0.2 V is applied to the unselected word lines during a read operation on a resistive memory array.

FIG. 8 is a graph illustrating the probability distribution for the electrical current through a selected primary bit line for a high resistance state of a selected resistive memory cell, the electrical current through a selected primary bit line for a low resistance state of the selected memory cell, and the electrical current through a selected complementary bit line according to an embodiment of the present disclosure.

FIG. 9 is a flow chart illustrating a sequence of steps for operating a resistive memory device of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element if the entire volume of the first element is located within a hypothetical volume defined by a set of hypothetical surfaces having the least total surface area among all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment among all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

According to an aspect of the present disclosure, a resistive memory device may comprise a primary memory array, a complementary memory array, and sense amplifiers. Each sense amplifier may have a first input node electrically connected to a primary bit line in the primary array and a second input node electrically connected to a complementary bit line in the complementary memory array. The primary bit line may be electrically connected to a column of primary memory cells, while the complementary bit line may be electrically connected to a column of complementary memory cells. During a read operation on a selected primary memory cell, the resistive memory device may use a word line biasing scheme to enhance sensing accuracy and reduce leakage currents. Specifically, the selected primary word line, which is electrically connected to the selected primary memory cell, may be electrically biased with a word line activation voltage to turn on the electrical current path within the selected primary memory cell. This activation voltage turns on the access transistor of the selected primary memory cell, allowing current to flow through the resistive memory element for sensing. Unselected primary word lines and all complementary word lines may be electrically biased with a leakage-current suppression voltage. This suppression voltage may have an opposite polarity to the word line activation voltage. In some embodiments, the leakage-current suppression voltage may be a negative voltage, while the word line activation voltage may be positive. The resistive state of the selected primary memory cell may then be sensed by generating an output voltage from a selected sense amplifier connected to the selected primary bit line.

The application of the leakage-current suppression voltage to the unselected word lines suppresses bit line leakage currents from unselected memory cells, which include unselected primary memory cells and all complementary memory cells. This suppression of leakage currents through application of the leakage-current suppression voltage may be particularly beneficial in resistive memory arrays with long bit lines or high cell density, where cumulative leakage from multiple unselected cells may impact sensing accuracy. This word line biasing scheme may increase the read window of a resistive memory device, thereby enhancing the reliability of sensing operations and potentially reducing read error rates. By reducing these leakage currents, the read window - defined as the difference between bit line currents for different resistive states - may be improved. This reduction of leakage currents may enhance the reliability of sensing the resistance states of RRAM cells, particularly in designs with long bit lines connected to a large number of resistive memory cells. The reduction in cumulative leakage through unselected resistive memory cells may lead to more accurate sensing of the resistive state of the selected resistive memory cell and may decrease read error rates.

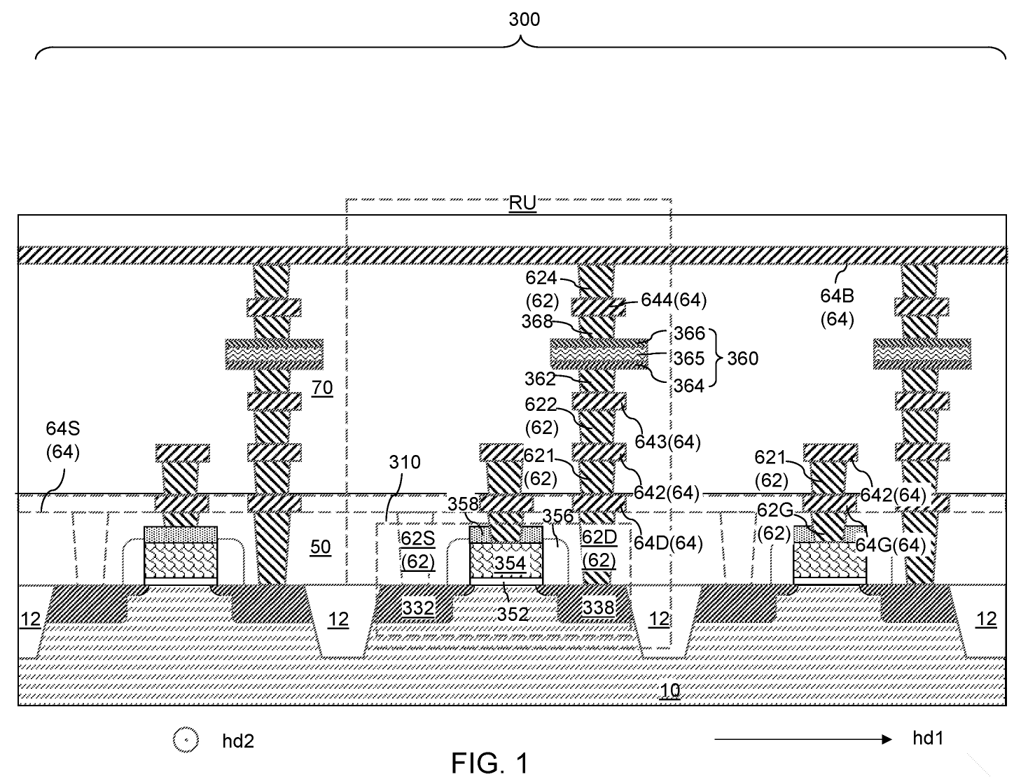

Referring to FIG. 1, a vertical cross-sectional view of an exemplary structure including a resistive random access memory device is illustrated. The exemplary structure comprises a semiconductor substrate 10, and an array of access transistors 310 that is formed on the semiconductor substrate 10 in a memory array region 300. The semiconductor substrate 10 may comprise a bulk semiconductor substrate or a semiconductor-on-insulator (SOI) substrate. The semiconductor substrate 10 may be a commercially available single crystalline silicon wafer.

Shallow trenches may be formed in an upper portion of the semiconductor substrate 10, and may be filled with a dielectric material to form shallow trench isolation structures 12. In one embodiment, the shallow trench isolation structures 12 may have a pattern of a grid containing a rectangular array of M x N openings therethrough. Each opening in the shallow trench isolation structures 12 defines an active region in which a source region 332, a drain region 338, and a channel region of a respective access transistor 310 is formed. The integer M may be in a range from 2 to 2¹⁶, although a greater number may also be used. The integer N may be in a range from 2 to 2¹⁶, although a greater number may also be used. Each active region may be located entirely within the area of a repetition unit RU in a plan view.

Generally, a two-dimensional array of resistive memory devices may be formed in the memory array region 300. Each resistive memory device may constitute a repetition unit RU of the two-dimensional array. Each resistive memory device may comprise an access transistor 310 that is formed on a top surface of the semiconductor substrate 10, a resistive memory element to be subsequently formed, and metal interconnect structures that are used to electrically connect a drain region of the access transistor 310 to an electrode of the resistive memory element, to electrically bias various nodes of the access transistor 310 and the resistive memory element.

For example, the two-dimensional array of resistive memory devices may comprise an M x N rectangular array of resistive memory devices including M rows and N columns. Each column of resistive memory devices may be arranged along a first horizontal direction hd1, and neighboring columns of resistive memory devices may be laterally spaced apart along a second horizontal direction hd2. Each row of resistive memory devices may be arranged along the second horizontal direction hd2, and neighboring rows of resistive memory devices may be laterally spaced apart along the first horizontal direction hd1. In one embodiment, each column of resistive memory devices may contain N resistive memory devices arranged along the first horizontal direction hd1. In one embodiment, each row of resistive memory device may contain M resistive memory devices arranged along the second horizontal direction hd2.

Specifically, a two-dimensional array of access transistors 310 may be formed on the semiconductor substrate 10. Each access transistor 310 comprises a source region 332, a drain region 338, a gate stack including a gate dielectric 352, a gate electrode 354, and a gate cap dielectric 358, and a gate spacer 356. The source region 332 may comprise a combination of a source extension region and a deep source region. The drain region 338 may comprise a combination of a drain extension region and a deep drain region. Each column of access transistors 310 may be arranged along the first horizontal direction hd1, and each row of access transistors 310 may be arranged along the second horizontal direction hd2.

Dielectric material layers may be formed over the two-dimensional array of access transistors 310. The dielectric material layers are herein referred to as lower-level dielectric material layers 50. Lower-level metal interconnect structures (62, 64) may be formed in the lower-level dielectric material layers 50. The lower-level metal interconnect structures (62, 64) may comprise metal via structures 62 and metal line structures 64. The level at which metal via structures contacting the source regions 332 or drain regions 338 are formed is herein referred to as a contact level. The metal via structures 62 that are formed at this processing step may comprise contact-level metal via structures (62S, 62D, 62G), i.e., metal via structures that are formed at the contact level. The contact-level metal via structures (62S, 62D, 62G) include source contact via structures 62S, drain contact via structures 62D, and gate contact via structures 62G.

The level at which metal lines that contact top surfaces of the contact-level metal via structures (62S, 62D, 62G) are formed is herein referred to as a first-metal-line level, i.e., a first level at which metal lines are formed as counted in the order of proximity to the semiconductor substrate 10. The metal line structures 64 that are formed at this processing step may comprise first-line-level metal lines (64S, 64D, 64G), i.e., metal line structures that are formed at the first-metal-line level, or an M1 level, which is a line level that is most proximal to the semiconductor substrate 10. The first-line-level metal lines (64S, 64D, 64G) may include, for example, source lines 64S, first-line-level drain-connection metal lines 64D, and first-line-level gate-connection metal lines 64G. The top surfaces of the first-line-level metal lines (64S, 64D, 64G) may be formed within a same horizontal plane.

In FIG. 1, the source lines 64S are represented by dotted lines to connote that the source lines 64S are laterally offset relative to neighboring first-line-level drain-connection metal lines 64D and first-line-level gate-connection metal lines 64G along the second horizontal direction hd2. Each source line 64S contacts a respective column of N source contact via structures 62S that are arranged along the first horizontal direction hd1, and is electrically connected to N source regions 332 in a respective column of N access transistors 310 that are arranged along the first horizontal direction hd1. The source contact via structures 62S may be laterally offset from relative to neighboring first-line-level drain-connection metal lines 64D and first-line-level gate-connection metal lines 64G along the second horizontal direction hd2, and thus, are represented by dotted lines in FIG. 1.

Each first-line-level drain-connection metal line 64D may have a configuration of a metal pad, may have a lesser area than the area of a respective underlying drain region 638, and may be electrically connected to the drain region 338 of a respective underlying access transistor 310 through a respective drain contact via structure 62D. Each first-line-level gate-connection metal lines 64G may have a configuration of a metal pad, may have a lesser area than the area of a respective underlying gate electrode, and may be electrically connected to the drain region 338 of a respective underlying access transistor 310 through a respective drain contact via structure 62D.

In one embodiment, all metal lines in the first metal line level may laterally extend along the first horizontal direction hd1 and may have a uniform lateral dimension, i.e., a uniform width, along the second horizontal direction hd2. Neighboring pairs of metal lines in the first metal line level may be laterally spaced from each other by a uniform lateral spacing. The sum of the uniform width of each first-line-level metal line (64S, 64D, 64G) and the uniform lateral spacing at the first metal line level defines a line pattern pitch of the first-line-level metal line (64S, 64D, 64G) along the second horizontal direction hd2.

The source lines 64S, the first-line-level drain-connection metal lines 64D, and the first-line-level gate-connection metal lines 64G may be located at the first metal line level. The first metal line level is vertically spaced from a top surface of the semiconductor substrate 10 by a first vertical spacing. The source lines 64S laterally extend along the first horizontal direction hd1, and are laterally spaced from each other along a second horizontal direction hd2. Each source region 332 within a column of access transistors 310 is electrically connected to each of the two source lines 64S that overlies the column of access transistors 310.

In one embodiment, each repetition unit RU may have a rectangular shape in a plan view, and the width of the rectangular shape of each repletion unit in the plan view along the second horizontal direction hd2 may be equal to an integer multiple of the line pattern pitch of the first-line-level metal lines (64S, 64D, 64G) along the second horizontal direction hd2. In other words, three metal lines of the same width along the second horizontal direction hd2 may fit into the rectangular area of a repetition unit RU.

Each first-line-level drain-connection metal line 64D may have a configuration of a metal pad, and may have a lateral extent along the first horizontal direction hd1 that is less than one half, and preferably less than one third, of the length of the rectangular shape of the repetition unit RU along the first horizontal direction hd1. The column of N first-line-level drain-connection metal lines 64D may be electrically connected to a column of drain regions 338 through a column of drain contact via structures 62D.

Each first-line-level gate-connection metal line 64G may have a configuration of a metal pad, and may have a lateral extent along the first horizontal direction hd1 that is less than one half, and preferably less than one third, of the length of the rectangular shape of the repetition unit RU along the first horizontal direction hd1. The column of N first-line-level gate-connection metal lines 64G may be electrically connected to a column of gate electrodes 354 through a column of gate contact via structures 62G.

Additional dielectric material layers and additional metal interconnect structures may be formed over the first-line-level metal lines (64S, 64D, 64G). The additional dielectric material layers are herein referred to as upper-level dielectric material layers 70. The additional metal interconnect structures are herein referred to as upper-level metal interconnect structures (62, 64). A two-dimensional array of resistive memory elements 360 may be formed within the upper-level dielectric material layers 70. The two-dimensional array of resistive memory elements 360 may be formed entirely within the memory array region 300 in a plan view.

The upper-level metal interconnect structures (62, 64) comprise metal via structures 62 that are formed at metal via levels within the memory array region 300 and metal line structures 64 that are formed at metal line levels within the memory array region 300. The metal line structures 64 within the upper-level metal interconnect structures (62, 64) are generally formed within the memory array region 300. Generally, the metal interconnect structures (62, 64) are embedded in dielectric material layers (50, 70), and are electrically connected to electrical nodes of the access transistors 310.

The metal line structures 64 may comprise second-line-level line structures 642 that are formed in a second-metal-line level, third-line-level line structures 643 that are formed in a third-metal-line level, fourth-line-level line structures 644 that are formed in a fourth-metal-line level, etc. Each n-th-metal-line level, or an Mn level, is a line level that is the n-th in the order of proximity to the semiconductor substrate 10 selected from all the metal line levels. The integer n may range from 2 to 20, although a greater number may also be used for the value of the integer n.

In one embodiment, a first subset of the metal line structures 64 that is formed at odd-numbered metal line levels may laterally extend along a horizontal direction (such as the first horizontal direction hd1), and a second subset of the metal line structures 64 that is formed at even-numbered metal line levels may laterally extend along another horizontal direction (such as the second horizontal direction hd2 that is perpendicular to the first horizontal direction hd1). For example, the source lines 64S and the first-line-level drain-connection metal lines 64D, the third-line-level line structures 643, etc. may laterally extend along the first horizontal direction hd1, and the second-line-level line structures 642, the fourth-line-level line structures 644, etc. may laterally extend along the second horizontal direction hd2.

The metal via structures 62 may comprise first-via-level connection via structures 621 that are formed in a first-metal-via level, second-via-level connection via structures 622 that are formed in a second-metal-via level, third-via-level connection via structures 623 that are formed in a third-metal-via level, etc. Each n-th-metal-via level, or a Vn level, is a via level that is the n-th in the order of proximity to the semiconductor substrate 10 selected from all the metal via levels excluding the contact via level. The integer n may range from 2 to 19, although a greater number may also be used for the value of the integer n.

A subset of the metal line structures 64 within the upper-level metal interconnect structures (62, 64) may comprise word lines 64W, which may laterally extend continuously along the second horizontal direction hd2 across areas of a respective row of access transistors 310 in a plan view. In some embodiments, the word lines 64W may be formed at an even-numbered metal line level. A subset of the metal via structures 62 and the metal line structures 64 may provide electrical connection to and from the gate electrodes 354 and the word lines 64W.

A subset of the metal line structures 64 within the upper-level metal interconnect structures (62, 64) may comprise bit lines 64B, which may laterally extend continuously along the first horizontal direction hd1 across areas of a respective column of access transistors 310 in the plan view. In some embodiments, the bit lines 64B may be formed at an odd-numbered metal line level other than the first metal line level. A subset of the metal via structures 62 and the metal line structures 64 may provide electrical connection to and from the second electrodes 366 of the resistive memory elements 360 and the bit lines 64B.

A resistive memory device may be formed within the volume of each repetition unit RU. Each resistive memory device may comprise an access transistor 310, a resistive memory element 360, and a subset of the metal interconnect structures (62, 64) that are located within the volume of a respective repetition unit RU. Each resistive memory element 360 may comprise a first electrode 364 (which may be a bottom electrode), a resistive memory material portion 365 comprising a material that provides at least two different resistive states, and a second electrode 366 (which may be a top electrode). The first electrode 364 may comprise a first inert metallic material such as TiN, TaN, WN, and/or MoN. Other suitable inert metallic materials may be within the contemplated scope of disclosure. The second electrode 366 may comprise a second inert metallic material such as TiN, TaN, WN, and/or MoN. The metal via structures 62 may comprise bottom-electrode-contact via structures 362 contacting bottom surfaces of the first electrodes 364 (which are bottom electrodes), and top-electrode-contact via structures 368 contacting top surfaces of the second electrodes 366 (which are top electrodes). Generally, the array of resistive memory elements 360 may be formed within a metal via level.

The material of each resistive memory material portion 365 that provides at least two different resistive states is herein referred to as a resistive memory material. Generally, the resistive memory material may be any type of resistive memory material known in the art. In one embodiment, the resistive memory material may comprise a conductive-filament-forming transition metal oxide material which may provide a higher conductivity upon formation of conductive filaments therein. The resistive memory element may be programmable between a low resistance state in which conductive filaments are present within the transition metal oxide material and a high resistance state in which the transition metal oxide material may be substantially free of the conductive filaments. Examples of such materials may include, but are not limited to, hafnium oxide, titanium oxide, niobium pentoxide, germanium telluride, silver sulfate, zinc oxide, vanadium oxide, tantalum oxide, and zirconium oxide. In one embodiment, the resistive memory material may include a filament-forming metal oxide that exhibits increased conductivity when conductive filaments are formed within it. This type of material may allow the resistive memory element to switch between two distinct states: a low resistance state characterized by the presence of conductive filaments within the metal oxide, and a high resistance state where the metal oxide is largely devoid of these filaments. Some examples of materials that may exhibit this behavior include hafnium oxide, titanium oxide, niobium pentoxide, germanium telluride, silver sulfate, zinc oxide, vanadium oxide, tantalum oxide, and zirconium oxide, and others.

In one embodiment, the resistive memory material may comprise a phase change memory material containing a chalcogenide glass (such as an alloy of germanium, antimony, and tellurium, and optionally additional additives). In one embodiment, the resistive memory material may comprise a conductive bridge-forming material in which conductive bridges may be formed or ruptured (such as silver, copper, silver sulfide, mixed ionic-electronic conductor materials (e.g., yttria-stabilized zirconia), etc.). In one embodiment, the resistive memory material may comprise an organic polymer material that may provide at least two different resistive states. In one embodiment, the resistive memory material may comprise a perovskite-based material that may provide at least two different resistive states. In one embodiment, the resistive memory material may comprise a two-dimensional material such as molybdenum disulfide (MoS₂) that may provide at least two different resistive states. In one embodiment, the resistive memory material may comprise an organic-inorganic hybrid resistive memory material that may provide at least two different resistive states. In one embodiment, the resistive memory material may comprise a rare earth oxide resistive memory material that may provide at least two different resistive states.

In embodiments in which the repetition unit RU is repeated in a pattern of an M x N rectangular array as discussed above, an M x N array of access transistors 310, an M x N array of resistive memory elements 360, and an M x N array of assemblies of metal interconnect structures (62, 64) may be provided. Each assembly of metal interconnect structures (62, 64) may be configured to provide electrical connections to a respective access transistor 310 and to a respective resistive memory element 360.

For each column of resistive memory elements 360 that is electrically connected to a column of access transistors 310, each resistive memory element 360 within the column of resistive memory elements 360 may be electrically connected to a drain region of a respective access transistor 310 within the column of access transistors 310. For each combination of a column of resistive memory elements 360 and a column of access transistors 310, two source lines 64S may be provided at a first metal line level that is vertically spaced from the top surface of the semiconductor substrate 10 by a first vertical spacing.

For each combination of a column of resistive memory elements 360 and a column of access transistors 310, a bit line 64B may be provided, which overlies a horizontal plane including top surfaces of the column of resistive memory elements 360 and is electrically connected to top electrodes within the column of resistive memory elements 360. Each bit line 64B may be electrically connected to a respective column of N resistive memory elements 360 via a respective subset of the metal interconnect structures. If the bit lines 64B are formed as a fifth-level metal line structures, the metal via structures 62 may include fourth-via-level connection via structures 624 that may be formed in a fourth-metal-via level, and each bit line 64B may contact a respective column of N fourth-via-level connection via structures 624 contacting a respective column of N fourth-line-level line structures 644.

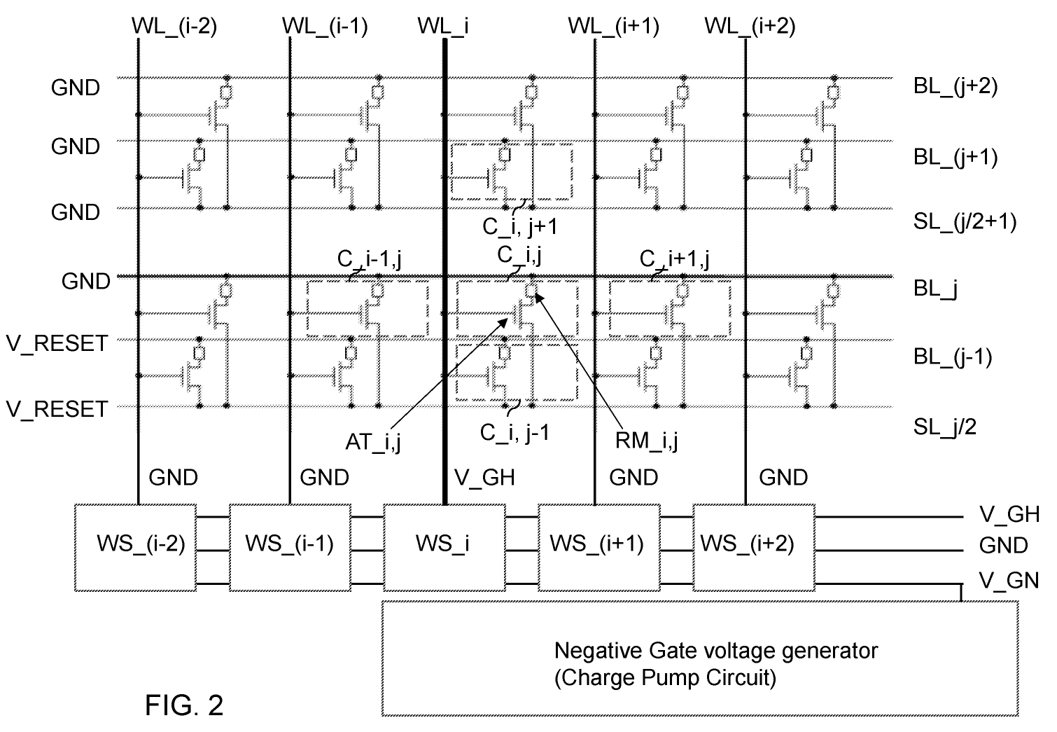

FIG. 2 illustrates a schematic circuit diagram of a portion of a resistive memory array and a subset of peripheral circuits during a reset operation. Generally, the resistive memory device of the present disclosure comprises a primary memory array, a complementary memory array, and sense amplifiers. The primary memory array and complementary memory array may each contain multiple memory cells arranged in rows and columns. In some embodiments, both the primary memory array and the complementary memory array may be configured to store data therein. In this embodiment, the resistive memory device of the present disclosure may comprise a first resistive memory array and a second resistive memory array having a symmetric configuration, and depending on the operational mode of the resistive memory device, the memory array on which a programming operation (also referred to as a set operation), an erase operation (also referred to as a reset operation), or a read operation (also referred to as a sensing operation) is performed is referred to as a primary memory array. The portion of the resistive memory array illustrated in FIG. 2 includes a portion of a primary memory array, of which a selected resistive memory cell is erased in a reset operation to be explained below.

Alternatively, the resistive memory array of the present disclosure may be configured to provide programming, erasing, and reading only on the primary memory array, while the complementary memory array functions as a circuit for generating a reference signal for read operations. In this embodiment, the primary memory array and the complementary memory array may be asymmetric.

Each sense amplifier may have a first input node connected to a primary bit line in the primary memory array and a second input node connected to a complementary bit line in the complementary memory array. The primary bit line may be connected to a column of primary memory cells within the primary memory array. Similarly, the complementary bit line may be connected to a column of complementary memory cells within the complementary memory array. This configuration may allow for differential sensing between the primary memory array and the complementary memory array.

In the primary memory array, each primary memory cell may comprise a series connection of a primary resistive memory element and a primary access transistor. Similarly, in the complementary memory array, each complementary memory cell may comprise a series connection of a complementary resistive memory element and a complementary access transistor. In one embodiment, the primary memory array may comprise an M x N array of primary memory cells in which M is the total number of the primary word lines and N is the total number of the primary bit lines. The complementary memory array may comprise an M x N array of complementary memory cells in which M is the total number of the complementary word lines and N is the total number of the complementary bit lines. In other words, the array size of the complementary memory array is the same as the array size of the primary memory array. The number M may be in a range from 2 to 2¹⁶, and the number N may be in a range from 2 to 2¹⁶.

The primary access transistors have gate electrodes that are electrically biased by primary word lines, respectively. Each primary word line may electrically bias a row of M gate electrodes of a row of M primary access transistors. The complementary access transistors have gate electrodes that are electrically biased by complementary word lines, respectively. Each complementary word line may electrically bias a row of M gate electrodes of a row of M complementary access transistors. The primary access transistors and the complementary access transistors may comprise access transistors 310 illustrated in FIG. 1.

Referring back to FIG. 2, the resistive memory elements within the primary memory cells and the complementary memory cells may utilize various types of resistive memory materials. In some embodiments, the resistive memory material may comprise a conductive-filament-forming transition metal oxide material. The resistance state of a memory cell may be altered by forming or disrupting conductive filaments within this oxide material. A low resistance state may correspond to the presence of conductive filaments, while a high resistance state may correspond to the absence or disruption of these filaments. Examples of such materials may include hafnium oxide, titanium oxide, niobium pentoxide, germanium telluride, silver sulfate, zinc oxide, vanadium oxide, tantalum oxide, and zirconium oxide. In other embodiments, the resistive memory material may comprise a phase change memory material containing a chalcogenide glass, a conductive bridge-forming material, an organic polymer material, a perovskite-based material, a two-dimensional material such as molybdenum disulfide, an organic-inorganic hybrid resistive memory material, or a rare earth oxide resistive memory material. Each of these materials may provide at least two different resistive states that may be used to store information in the memory cell. The resistive memory elements within the primary memory array and the complementary memory array may comprise the resistive memory elements 360 illustrated in FIG. 1.

The word lines of a memory array may be numbered with non-negative integers or positive integers. In an illustrative example, each word line (which may be a primary word line or a complementary word line) may be numbered with a row index i that runs from 1 to M. In the present disclosure, the i-th word line is labeled as WL_i, and so forth. The word lines may comprise a subset of second-line-level line structures 642 that are electrically connected to respective rows of gate electrodes 354 in the exemplary structure of FIG. 1. Each word line is driven by a respective word line driver, which is also referred to as a word line switch. In the present disclosure, the i-th word line switch is labeled as WS_i, and so forth.

The bit lines of a memory array may be numbered with non-negative integers or positive integers. In an illustrative example, each bit line (which may be a primary bit line or a complementary bit line) may be numbered with a bit line index j that runs from 1 to N. In the present disclosure, the j-th bit line is labeled as BL_j, and so forth. The bit lines may comprise the bit lines 64B illustrated in FIG. 1.

The source lines of a memory array may be numbered with non-negative integers or positive integers. In an illustrative example, each source line may be electrically connected to two columns of resistive memory cells (including 2N resistive memory cells). In the present disclosure, a j/2-th source line is labeled as SL_j/2, and so forth. If N is an even number, a total of N/2 source lines may be provided within each memory array. The source lines may comprise a subset of the metal lines such as the source lines 64S illustrated in FIG. 1.

Referring back to FIG. 2, each resistive memory cell may be identified by the word line and the bit line that actuates the respective memory cell. Thus, each resistive memory cell may be numbered with a two-dimensional vector, or a Cartesian coordinate, represented by (i, j), in which the integer i is the number assigned to the word line and the integer j is the integer assigned to the bit line. A resistive memory cell accessed by the i-th word line and the j-th bit line is referred to as an i-th row j-th column resistive memory cell C_i,j. The access transistor within the i-th row j-th column resistive memory cell C_i,j is herein referred to as an i-th row j-th column access transistor AT_i,j. The resistive memory element within the i-th row j-th column resistive memory cell C_i,j is herein referred to as an i-th row j-th resistive memory element RM_i,j.

The illustrated portion of the primary memory array includes multiple word lines, such as a (i-2)-th word line WL_(i-2), a (i-1)-th word line WL_(i-1), an i-th word line WL_i, a (i+1)-th word line WL_(i+1), and a (i+2)-th word line WL_(i+2). The illustrated portion of the primary memory array also includes multiple bit lines, such as a (j-1)-th bit line BL_(j-1), a j-th bit line BL_j, a (j+1)-th bit line BL_(j+1), and a (j+2)-th bit line BL_(j+2). The illustrated portion of the primary memory array may include source lines, such as a j/2-th source line SL_j/2 and a (j/2+1)-th source line SL_(j/2+1). The illustrated portion of the primary memory array further includes word line switches, such as a (j-2)-th word line switch WS_(j-2), a (i-1)-th word line switch WS_(i-1), a j-th word line switch WS_j, a (i+1)-th word line switch WS_(j+1), and a (j+2)-th word line switch WS_(j+2). The word line switches may control the application of voltages to the corresponding word lines.

During a reset operation, the resistive memory device may program a selected memory cell to a high resistance state. The pre-existing state of the selected memory cell may be a low resistance state or the high resistance state. In embodiments in which the resistive memory material portion of the selected memory cell comprises a filament-forming dielectric metal oxide material, the reset operation may remove conductive filaments within the filament-forming dielectric metal oxide material of the primary resistive memory element.

To perform the reset operation, a voltage differential of V_RESET is generated between the source line and the bit line that are connected to the selected memory cell; all word lines that are not connected to the selected memory cell are biased at the electrical ground GND (which may be at 0 V); and the word line connected to the access transistor in the selected memory cell may be pulsed with an electrical pulse having a steady state voltage that equals a gate turn-on voltage V_GH. The magnitude of the reset voltage V_RESET, the magnitude of the gate turn-on voltage V_GH, and the duration of the pulse of the gate turn-on voltage V_GH may be controlled to ensure reliable transition of the resistive memory element of the selected memory cell into a high resistance state. In an illustrative example, the selected source line (i.e., the source line connected to the selected memory cell such as SL_j/2) may be biased at V_RESET, the selected bit line (i.e., the bit line connected to the selected memory cell such as BL_j) may be biased at the electrical ground GND, any additional bit line that is connected to the selected source line (such as BL_(j-1)) may be biased at V_RESET, and all other source lines and all other bit lines may be biased at the electrical ground GND.

During the reset operation, the bit line connected to the selected memory cell may be biased with a reset voltage V_RESET, which may have a negative polarity relative to the electrical ground GND. The unselected word lines and all source lines may be biased at the electrical ground GND (which may be at 0 V), and the word line connected to the access transistor in the selected memory cell may be pulsed with an electrical pulse having a steady state voltage that equals a gate turn-on voltage V_GH. The magnitude of the reset voltage V_RESET, the magnitude of the gate turn-on voltage V_GH, and the duration of the pulse of the gate turn-on voltage V_GH may be controlled to ensure reliable transition of the resistive memory element of the selected memory cell into a high resistance state.

In a non-limiting illustrative example, the reset voltage V_RESET may be in a range from -1.5 V to -3.5 V, while the gate turn-on voltage V_GH may be in a range from 1.8 V to 2.5 V. The duration of the reset programming pulse applied to the selected word line may be in a range from 50 nanoseconds to 500 nanoseconds. These voltage ranges and pulse durations may be adjusted based on factors such as the specific resistive memory material used, the desired switching speed, and the overall power consumption desired for use with the device. In some embodiments, the reset voltage V_RESET may be applied to the bit line for a duration that is longer than the gate turn-on voltage V_GH pulse applied to the word line, which may help ensure complete disruption of conductive filaments while minimizing unnecessary current flow through the access transistor.

Generally, the word line switches may be connected to three power supply voltages, which include the gate turn-on voltage V_GH, the electrical ground GND, and a leakage-current suppression voltage V_GN. The leakage-current suppression voltage V_GN has the opposite polarity of the gate turn-on voltage V_GH, and if applied to a gate electrode, has the effect of reducing the leakage current of the access transistor including the gate electrode. The leakage-current suppression voltage V_GN may be generated using a negative gate voltage generator circuit, which may comprise a charge pump circuit. In an illustrative example, the leakage-current suppression voltage V_GN may be in a range from -0.05 V to -0.5 V, such as from -0.1 V to -0.3 V, although lesser or greater voltages may also be used. The leakage-current suppression voltage V_GN is not used during the reset operation.

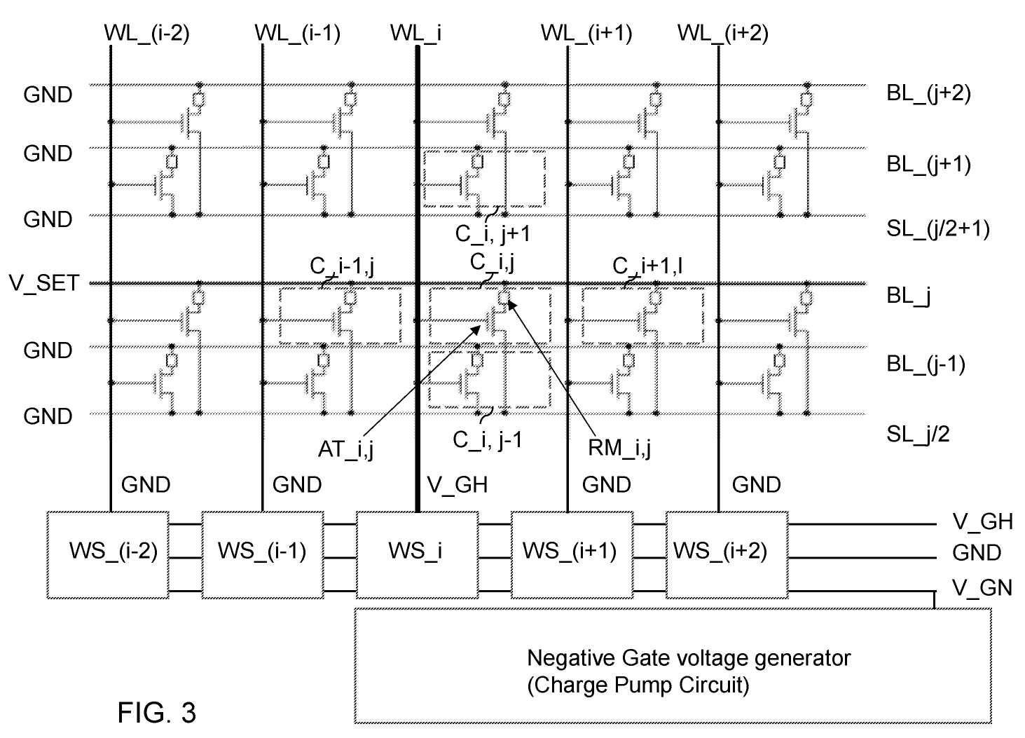

FIG. 3 illustrates a schematic circuit diagram of the portion of the resistive memory array and the subset of peripheral circuits illustrated in FIG. 2 during a set operation. During a set operation, the resistive memory device may program a selected memory cell from a high resistance state to a low resistance state. In some embodiments, the set operation may involve formation of conductive filaments within a filament-forming transition metal oxide material portion of the selected resistive memory element.

To perform the set operation, the bit line connected to the selected memory cell may be biased with a set voltage V_SET, which may have a positive polarity relative to the electrical ground GND. The unselected word lines and all source lines may be biased at the electrical ground GND (which may be at 0 V), and the word line connected to the access transistor in the selected memory cell may be pulsed with an electrical pulse having a steady state voltage that equals a gate turn-on voltage V_GH. The magnitude of the set voltage V_SET, the magnitude of the gate turn-on voltage V_GH, and the duration of the pulse of the gate turn-on voltage V_GH may be controlled to ensure reliable transition of the resistive memory element of the selected memory cell into a low resistance state.

During the set operation, the bit line connected to the selected memory cell may be biased with a set voltage V_SET for a relatively long duration. This extended application of V_SET may help ensure sufficient time for the conductive filaments within the resistive memory element of the selected memory cell to be formed, thereby reliably transitioning the selected memory cell to a low resistance state. In contrast, the word line connected to the access transistor in the selected memory cell may be pulsed with a shorter electrical pulse having a steady state voltage that equals a gate turn-on voltage V_GH. This shorter pulse duration for the gate voltage may help limit current flow through the access transistor, potentially improving energy efficiency and preventing excessive heat generation or damage to the device.

In a non-limiting illustrative example, the set voltage V_SET may be in a range from 1.0 V to 3.0 V, while the gate turn-on voltage V_GH may be in a range from 1.8 V to 2.5 V. The duration of the set programming pulse applied to the selected word line may be in a range from 50 nanoseconds to 500 nanoseconds. These voltage ranges and pulse durations may be adjusted based on factors such as the specific resistive memory material used, the desired switching speed, and the overall power consumption desired for use of the device. In some embodiments, the set voltage V_SET may be applied to the bit line for a duration that is longer than the gate turn-on voltage V_GH pulse applied to the word line, which may help ensure complete formation of conductive filaments while minimizing unnecessary current flow through the access transistor.

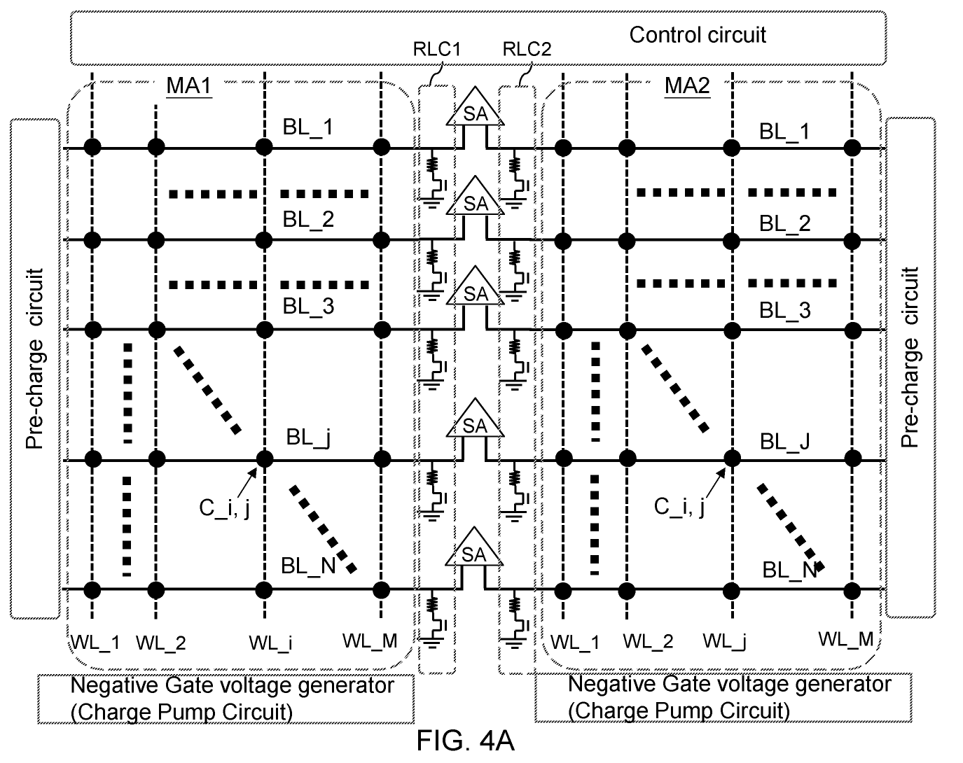

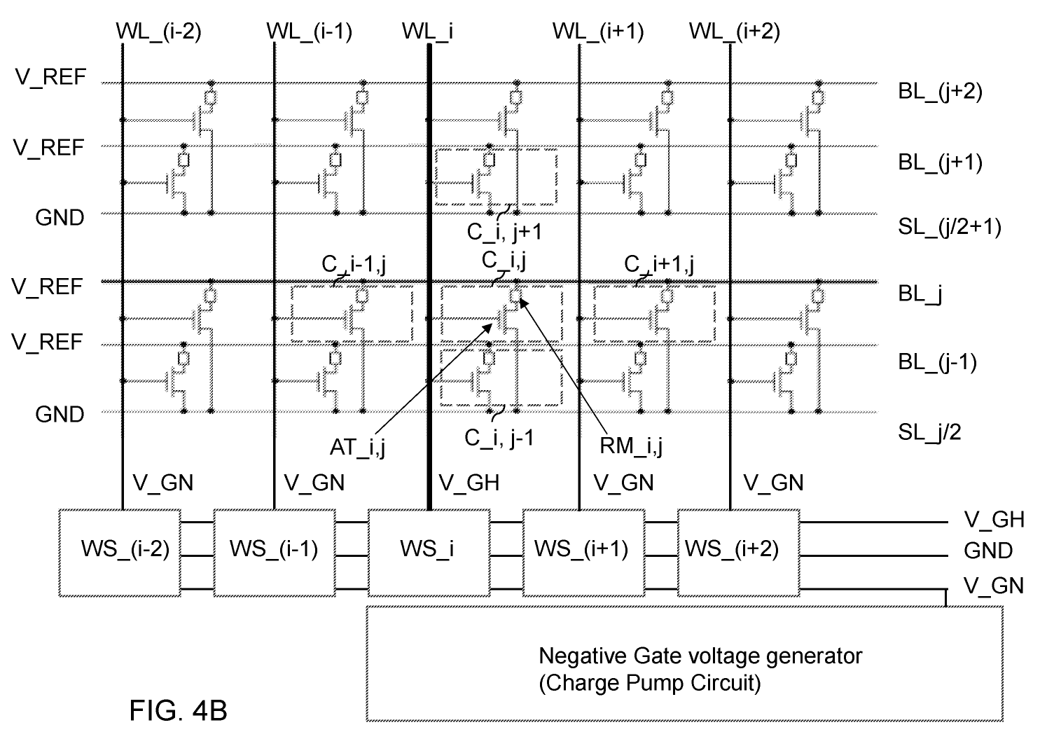

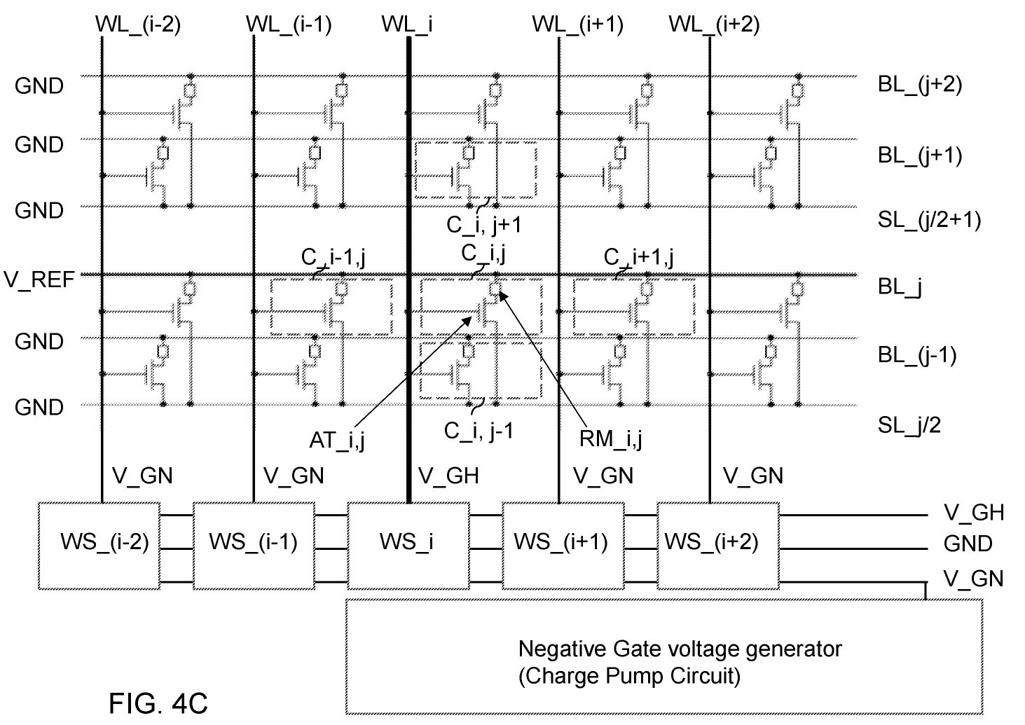

FIG. 4A illustrates a first exemplary resistive memory device. The first exemplary resistive memory device may include a first memory array MA1, a second memory array MA2, sense amplifiers, a first reference leakage circuit RLC1, a second reference leakage circuit RLC2, two pre-charge circuits, negative gate voltage generators, and a control circuit. The first memory array MA1 and the second memory array MA2 may each include M word lines and N bit lines and an M x N array of resistive memory cells. The first exemplary resistive memory device may store data in the first memory array MA1 and in the second memory array MA2. The sensing operation may be performed sequentially between the first memory array MA1 and the second memory array MA2. In other words, only one memory array may be sensed at one time, and thus, reading data from the second memory array MA2 precedes or follows reading data from the first memory array MA1. The memory array from which data is read during the sensing operation functions as the primary memory array for the purpose of sensing, and the memory array from which data is not read during the sensing operation functions as the complementary memory array. In the illustrated configuration, data is read from the first memory array MA1, and thus, the first memory array MA1 functions as the primary memory array and the second memory array MA2 functions as the complementary memory array. Subsequently, when data is read from the second memory array MA2, the second memory array MA2 may function as the primary memory array and the first memory array MA1 may function as the complementary memory array.

In one embodiment, the resistive memory cells in the first memory array MA1 and the resistive memory cells in the second memory array MA2 may be identical in design, and may be structurally the same within the limit of manufacturing tolerances, i.e., variations that are unintentionally but inherently introduced during a manufacturing sequence. Thus, irrespective of which memory array is used as a primary memory array and which memory array is used as a complementary memory array, the device characteristics of the first memory array MA1 and the second memory array MA2 are identical. In one embodiment, the complementary access transistors and the primary access transistors may have a same set of a nominal gate thickness, a nominal gate length, a nominal gate width, and a gate electrode material composition. Further, the resistive memory elements in the first memory array MA1 and the resistive memory elements in the second memory array MA2 may be identical in design. The identical design of the primary memory cells and the complementary memory cells ensures identical device characteristics between the primary memory array and the complementary memory arrays. A read operation may be performed on at least one selected primary memory cell to determine the resistive state of each of the at least one selected primary memory cell.

FIG. 4B illustrates an operational mode in which the at least one selected primary memory cell may comprise a row of N primary memory cells that is connected to a selected word line such as an i-th word line. In this embodiment, data stored in a row of primary memory cells C_i,k, in which i is a fixed integer and k is a running index that runs from 1 to N, may be read simultaneously using N bit lines. Generally, a sequence of steps are performed during a read operation as will be explained below. The voltage application scheme illustrated in FIG. 4B corresponds to a step at which a reference voltage V_REF is applied to the j-th bit line.

Referring collectively to FIGS. 4A and 4B, a selected primary word line (e.g., the i-th word line WL_i) may be electrically biased with a word line activation voltage, which may be the gate turn-on voltage V_GH. All access transistors connected to the selected primary word line are turned on. According to an aspect of the present disclosure, a leakage-current suppression voltage may be applied to all unselected word lines in the primary memory array and to all word lines in the complementary memory array. The leakage-current suppression voltage has an opposite polarity relative to the gate turn-on voltage V_GH. For example, in instances in which the gate turn-on voltage V_GH is a positive voltage, the leakage-current suppression voltage may be a negative voltage. In an illustrative example, the leakage-current suppression voltage may be in a range from -0.05 V to -0.5 V, such as from -0.1 V to -0.3V. In one embodiment, the gate turn-on voltage V_GH may reduce the gate leakage current at least by one order of magnitude, and preferably at least by two orders of magnitude, and more preferably at least by three orders of magnitude, compared to a baseline case in which the gate electrodes are electrically biased at the electrical ground, i.e., at 0 V.

Application of the leakage-current suppression voltage to all unselected word lines in the primary memory array and to all word lines in the complementary memory array reduces the leakage current between each primary bit line and the electrical ground, and reduces the leakage current between each complementary bit line and the electrical ground. Reduction of the leakage current between the primary bit lines and the electrical ground and between the complementary bit lines and the electrical ground increases the sensing margin and reliability of the read operation.

According to an aspect of the present disclosure, the complementary memory array serves as a source for a reference signal for the purpose of sensing the resistive state of the selected primary memory cells during the read operation. Application of the leakage-current suppression voltage to all unselected word lines in the primary memory array causes the leakage current between the primary bit lines and the electrical ground to be dominated by the electrical current through the row of selected resistive memory cells, i.e., C_i,k in which i is a fixed index and k is a running index that runs between 1 and N. Further, application of the leakage-current suppression voltage to all word lines in the complementary memory array effectively eliminates the leakage current between the complementary bit lines and the electrical ground.

In order to provide a reference leakage current that is greater than the leakage current through a turned-on resistive memory cell (i.e., a memory cell of which the access transistor is turned on) having a high resistance state and is less than the leakage current through a turned-on resistive memory cell (i.e., a memory cell of which the access transistor is turned on) having a low resistance state, the second reference leakage circuit RLC2 is turned on. The second reference leakage circuit RLC2 comprises N series connections of an access transistor and a reference resistor. Each series connection of an access transistor and a reference resistor is connected between a respective bit line in the second memory array MA and the electrical ground GND. Each reference resistor has a resistance that is higher than the resistance of a resistive memory element having a low resistance state, and is lower than the resistance of a resistive memory element having a high resistance state. In one embodiment, the value of the resistance of each reference resistor is selected such that the leakage current through a series connection of an access transistor and a reference resistor is midway between the leakage current through a turned-on resistive memory cell having a high resistance state and the leakage current through a turned-on resistive memory cell having a low resistance state.

The read operation may include a pre-charge step where each selected primary bit line and each selected complementary bit line are electrically biased at a bit line bias voltage, which is also referred to as a reference voltage V_REF, prior to a read output generation step. For each selected primary bit line, a corresponding complementary bit line connected to a same sense amplifier is also selected. In the example illustrated in FIG. 4B, all primary bit lines and all complementary bit lines are simultaneously selected to provide sensing of data from a selected row of primary memory cells, such as primary memory cells C_i,k in which i is a fixed index and k is a running index that runs from 1 to N. During the pre-charge step, each selected primary bit line and each selected complementary bit line functions as an electrode of a respective capacitor that is charged to the reference voltage V_REF as illustrated in FIG. 4B. Upon termination of the pre-charge step, the voltage source that applies the reference voltage V_REF is disconnected from each selected primary bit line and from each selected complementary bit line. At this step, each selected primary bit line and each selected complementary bit line become an electrically floating electrode of a respective capacitor.

However, the selected primary bit lines and the selected complementary bit lines are not perfectly electrically floating once the voltage source for the reference voltage V_REF is disconnected. For each selected primary bit line, the predominant leakage source is a selected resistive memory cell that is connected to the respective selected primary bit line. The access transistor of the selected resistive memory cell is turned on, and the leakage current between the respective selected primary bit line and the electrical ground is inversely proportional to the resistance of the resistive memory element that is connected to the access transistor. Further, for each selected complementary bit line, the predominant leakage source is a series connection of an access transistor and a reference resistor in the second reference leakage circuit RLC2 that is connected to the respective selected complementary bit line. The access transistor in the series connection is turned on, and the leakage current between the respective selected complementary bit line and the electrical ground is inversely proportional to the resistance of the reference resistor that is connected to the access transistor.

For each pair of a selected primary bit line and a complementary bit line that is connected to the input nodes of a respective sense amplifier, the resistive state of the selected primary memory cell connected to the selected primary bit line may be sensed by generating output voltages from the respective sense amplifiers. In the operational mode illustrated in FIG. 4B, N outputs from N sense amplifiers may be simultaneously generated, which represent data stored in the selected row of primary resistive memory cells (such as the primary resistive memory cells located in the i-th row of the primary memory array).

In some embodiments, not every sense amplifier in the resistive memory array may be used for sensing. FIG. 4C illustrates a second type of read operation where only a single data bit stored in a selected resistive memory cell is read by activating a single sense amplifier. In the illustrated example in FIG. 4C, only the data stored in the i-th row j-th column primary memory cell C_i,j may be sensed by activating the i-th primary word line, the j-th primary bit line, and the j-th complementary bit line, by applying a leakage-current suppression voltage to all other word lines, and by electrically grounding all other bit lines and the source lines.

Referring collectively to FIGS. 4A, 4B, and 4C, a method of operating a resistive memory device may include providing a resistive memory device comprising a primary memory array, a complementary memory array, and sense amplifiers. Each of the sense amplifiers may comprise a respective first input node connected to a respective primary bit line in the primary array and a respective second input node connected to a respective complementary bit line in the complementary memory array. The respective primary bit line may be connected to a respective column of primary memory cells and the respective complementary bit line may be connected to a respective column of complementary memory cells.

In one embodiment, the method may include performing a read operation on a selected primary memory cell that is accessed by a selected primary word line and a selected primary bit line. The read operation may include a word line bias application step and a read output generation step. In the word line bias application step, the selected primary word line may be electrically biased with a word line activation voltage and unselected primary word lines may be electrically biased with a leakage-current suppression voltage having an opposite polarity of the word line activation voltage. In the read output generation step, a resistive state of the selected primary memory cell may be sensed by generating an output voltage from a selected sense amplifier that is connected to the selected primary bit line.

In one embodiment, the method may further include electrically biasing all complementary word lines in the complementary memory array with the leakage-current suppression voltage while performing the read output generation step. This may help to reduce leakage currents in the complementary memory array during the read operation.

In one embodiment, the respective column of primary memory cells may comprise a respective set of M primary memory cells, and the respective column of complementary memory cells may comprise a respective set of M complementary memory cells. M may be an integer in a range from 2 to 2¹⁶. This configuration may allow for a high-density memory array with a large number of memory cells per bit line.

In one embodiment, the read operation may comprise a pre-charge step in which the selected primary bit line and a selected complementary bit line that is connected to the second input node of the selected sense amplifier are electrically biased at a bit line bias voltage prior to performing the read output generation step. This pre-charge step establishes a known initial voltage on the bit lines before sensing the resistive state of the selected memory cell.

In one embodiment, the resistive memory device may comprise a complementary reference leakage circuit that is attached to the complementary bit lines and configured to provide a reference leakage current to each of the complementary bit lines. The method may comprise activating a reference leakage path within the complementary reference leakage circuit that is connected to the selected complementary bit line prior to performing the read output generation step. This reference leakage circuit may help to establish a reference current for comparison during the sensing operation.

In one embodiment, each of the primary memory cells in the primary memory array may comprise a series connection of a respective primary resistive memory element and a respective primary access transistor having a respective primary gate electrode that is electrically biased by a respective one of primary word lines. Each of the primary access transistors may comprise a respective source region that is electrically grounded during the word line bias application step. This configuration allows for selective access to individual memory cells within the array.

In one embodiment, each of the complementary memory cells in the complementary memory array may comprise a series connection of a respective complementary resistive memory element and a respective complementary access transistor having a respective complementary gate electrode that is electrically biased by a respective one of complementary word lines. The complementary access transistors and the primary access transistors may have a same set of a nominal gate thickness, a nominal gate length, a nominal gate width, and a gate electrode material composition. This similarity in transistor characteristics may help ensure uniform performance across both the primary and complementary memory arrays.

In one embodiment, the respective primary resistive memory element may comprise a conductive-filament-forming transition metal oxide material. The method may comprise programming a primary resistive memory element of the selected primary memory cell into a target resistance state that is selected from a low resistance state in which conductive filaments are present within the primary resistive memory element and a high resistance state in which the primary resistive memory element is substantially free of the conductive filaments. This allows for the storage of binary data within each memory cell.

In one embodiment, the method may further comprise storing a data bit in a selected complementary memory cell that is accessed by a selected complementary word line and a selected complementary bit line within the complementary memory array. The method may also include performing an additional read operation on the selected complementary memory cell. This additional read operation may include an additional word line bias application step of electrically biasing the selected complementary word line with the word line activation voltage and electrically biasing unselected complementary word lines with the leakage-current suppression voltage. The additional read operation may also include an additional read output generation step of sensing a resistive state of the selected complementary memory cell by generating an output voltage from an additional selected sense amplifier that is connected to the selected complementary bit line. This configuration allows for the complementary memory array to be used for data storage in addition to providing reference signals, potentially increasing the overall storage capacity of the device. Generally, reading data from the second memory array MA2 may be effected by performing the read operation described on the second memory array MA2 instead of the first memory array MA1 in a manner in which the function of the first memory array MA1 and the function of the second memory array MA2 are swapped, and the first reference leakage current circuit RLC1 is used in lieu of the second reference leakage current circuit RLC2.

In an embodiment, the method may further include the step of electrically biasing all primary word lines in the primary memory array with the leakage-current suppression voltage while performing the additional read output generation step.

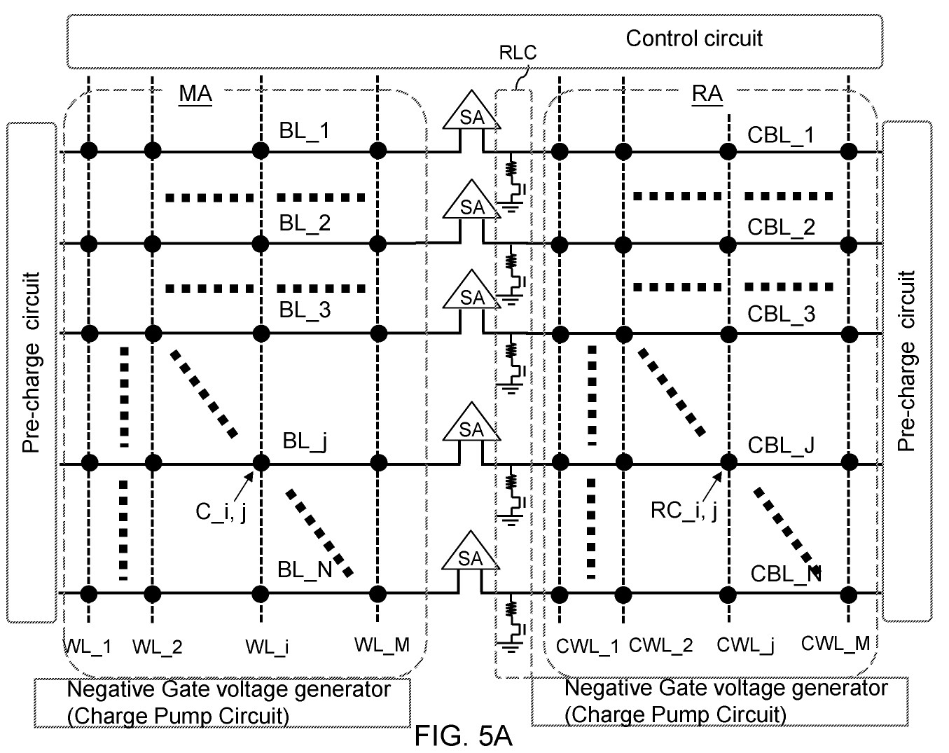

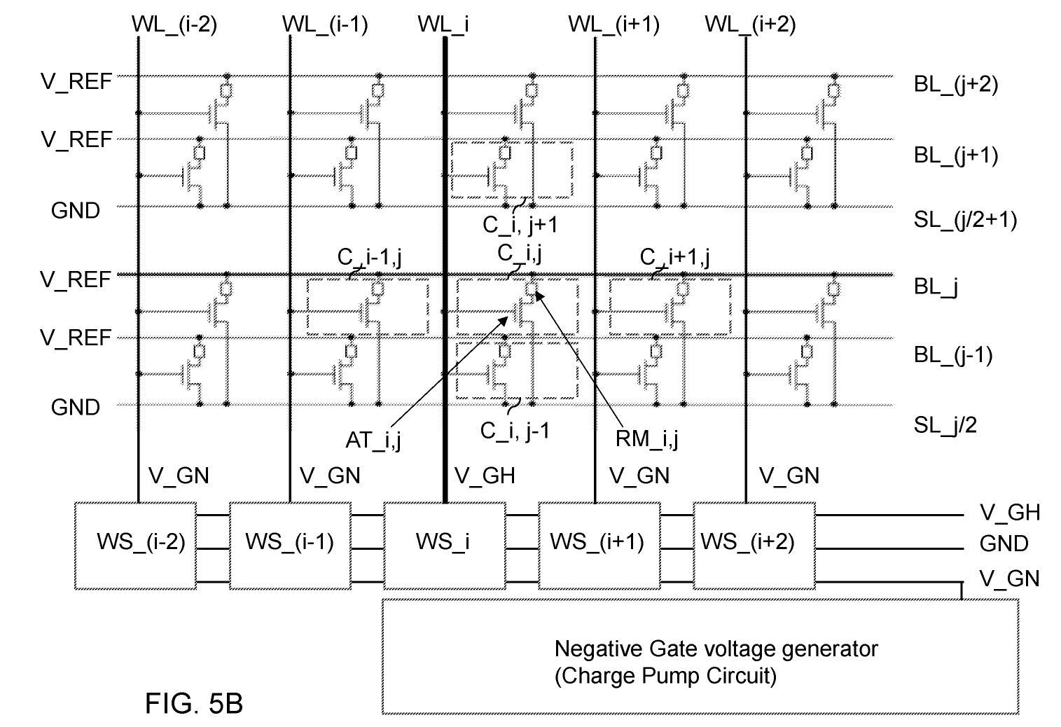

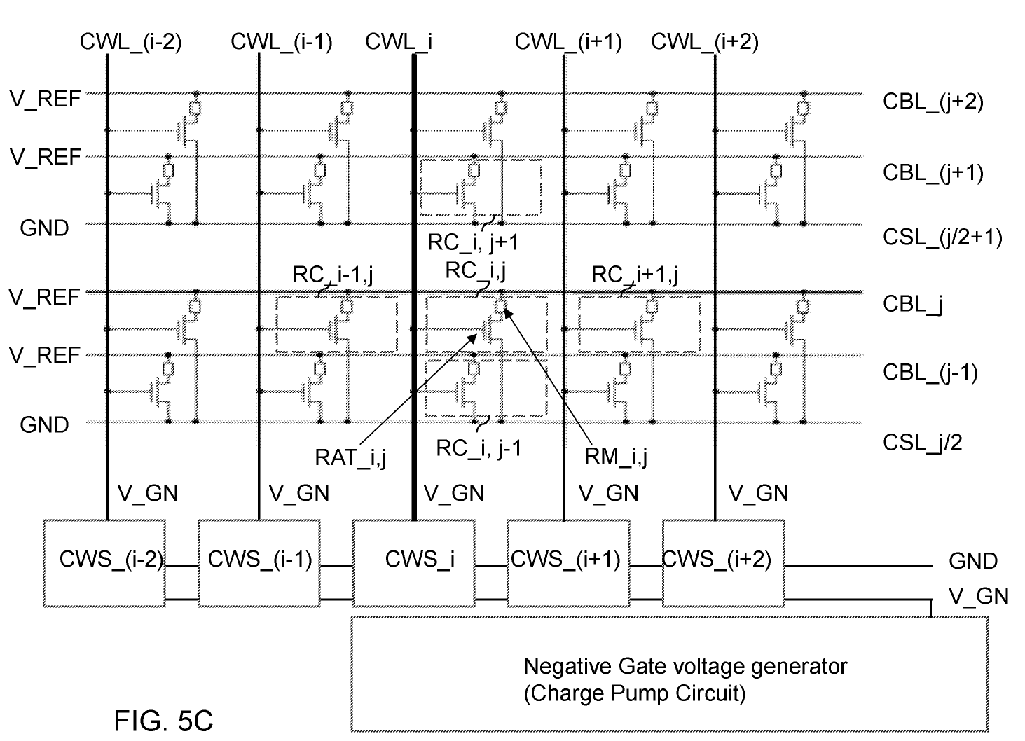

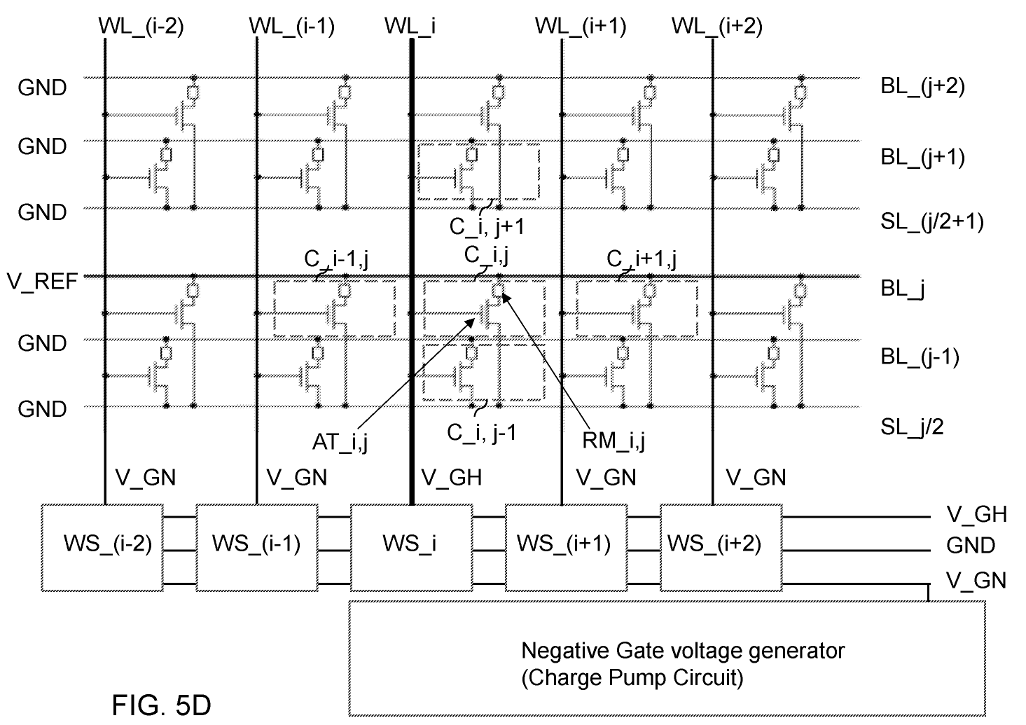

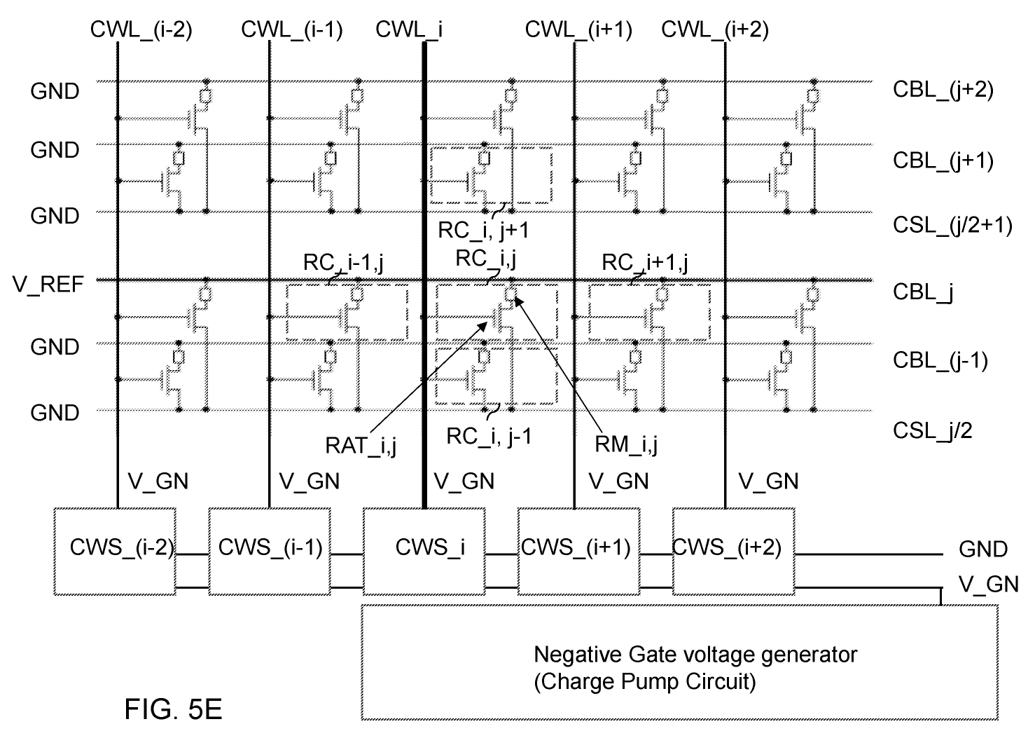

FIG. 5A illustrates a second exemplary resistive memory device. The second exemplary resistive memory device may include a memory array MA configured to store data therein, sense amplifiers, a reference array RA that is not configured to store data therein but is configured to generate reference signals for the sense amplifiers, a reference leakage circuit RLC, two pre-charge circuits, negative gate voltage generators, and a control circuit. The memory array M1 and the reference array RA may each include M word lines and N bit lines and an M x N array of resistive memory cells. The second exemplary resistive memory device may store data in the memory array MA, but not in the reference array RA. Thus, the sensing operation may be performed to retrieve data the memory array MA, while the reference array RA functions to provide reference signals for sensing. Thus, the memory array MA functions as the primary memory array, and the reference array RA functions as the complementary memory array.

In view of the fact that the bit lines in the reference array RA function only as complementary bit lines, the bit lines in the reference array RA are referred to as complementary bit lines CBL_j, in which the index j may have a value not less than 1 and not greater than N. Further, in view of the fact that the word lines in the reference array RA function only as complementary word lines, the word lines in the reference array RA are referred to as complementary word lines CWL_i, in which the index i may have a value not less than 1 and not greater than M.

In one embodiment, the primary memory cells in the memory array MA1 and the complementary memory cells in the reference array RA may be identical in design, and may be structurally the same within the limit of manufacturing tolerances, i.e., variations that are unintentionally but inherently introduced during a manufacturing sequence. The device characteristics of the memory array MA and the reference array RA are identical. In one embodiment, the complementary access transistors and the primary access transistors may have a same set of a nominal gate thickness, a nominal gate length, a nominal gate width, and a gate electrode material composition. Further, the resistive memory elements in the memory array MA and the resistive memory elements in the reference array RA may be identical in design. The identical design of the primary memory cells and the complementary memory cells ensures identical device characteristics between the primary memory array and the complementary memory arrays. A read operation may be performed on at least one selected primary memory cell to determine the resistive state of each of the at least one selected primary memory cell.

FIGS. 5B and 5C illustrate an operational mode in which the at least one selected primary memory cell may comprise a row of N primary memory cells that is connected to a selected word line such as an i-th word line. FIG. 5B illustrates a portion of the memory array MA, and FIG. 5C illustrates a portion of the reference array RA. In this embodiment, data stored in a row of primary memory cells C_i,k, in which i is a fixed integer and k is a running index that runs from 1 to N, may be read simultaneously using N bit lines. The word line switches in the reference array RA are herein referred to as complementary word line switches CWS_i, in which the index i has a range from 1 to M. The resistive memory cells in the reference array RA do not undergo programming, erasure, or read operations. Thus, there is no need to provide the gate turn-on voltage V_GH to the reference array RA.

Referring collectively to FIGS. 5A, 5B, and 5C, a selected primary word line (e.g., the i-th word line WL_i) may be electrically biased with a word line activation voltage, which may be the gate turn-on voltage V_GH. All access transistors connected to the selected primary word line are turned on. According to an aspect of the present disclosure, a leakage-current suppression voltage may be applied to all unselected word lines in the primary memory array and to all word lines in the complementary memory array. The leakage-current suppression voltage has an opposite polarity relative to the gate turn-on voltage V_GH. For example, if the gate turn-on voltage V_GH is a positive voltage, the leakage-current suppression voltage may be a negative voltage. In an illustrative example, the leakage-current suppression voltage may be in a range from -0.05 V to -0.5 V, such as from -0.1 V to -0.3V. In one embodiment, the gate turn-on voltage V_GH may reduce the gate leakage current at least by one order of magnitude, and preferably at least by two orders of magnitude, and more preferably at least by three orders of magnitude, compared to a baseline case in which the gate electrodes are electrically biased at the electrical ground, i.e., at 0 V.

Application of the leakage-current suppression voltage to all unselected word lines in the primary memory array and to all word lines in the complementary memory array reduces the leakage current between each primary bit line and the electrical ground, and reduces the leakage current between each complementary bit line and the electrical ground. Reduction of the leakage current between the primary bit lines and the electrical ground and between the complementary bit lines and the electrical ground increases the sensing margin and reliability of the read operation.

According to an aspect of the present disclosure, the complementary memory array serves as a source for a reference signal for the purpose of sensing the resistive state of the selected primary memory cells during the read operation. Application of the leakage-current suppression voltage to all unselected word lines in the primary memory array causes the leakage current between the primary bit lines and the electrical ground to be dominated by the electrical current through the row of selected resistive memory cells, i.e., C_i,k in which i is a fixed index and k is a running index that runs between 1 and N. Further, application of the leakage-current suppression voltage to all word lines in the complementary memory array effectively eliminates the leakage current between the complementary bit lines and the electrical ground. The identical structural characteristic between the memory array MA (which is the primary memory array) and the reference array RA (which is the complementary memory array) ensures that the background leakage characteristics are also the same across the memory array MA and the reference array RA.

In order to provide a reference leakage current that is greater than the leakage current through a turned-on resistive memory cell (i.e., a memory cell of which the access transistor is turned on) having a high resistance state and is less than the leakage current through a turned-on resistive memory cell (i.e., a memory cell of which the access transistor is turned on) having a low resistance state, the reference leakage circuit RLC is turned on. The reference leakage circuit RLC comprises N series connections of an access transistor and a reference resistor. Each series connection of an access transistor and a reference resistor is connected between a respective bit line in the second memory array MA and the electrical ground GND. Each reference resistor has a resistance that is higher than the resistance of a resistive memory element having a low resistance state, and is lower than the resistance of a resistive memory element having a high resistance state. In one embodiment, the value of the resistance of each reference resistor is selected such that the leakage current through a series connection of an access transistor and a reference resistor is midway between the leakage current through a turned-on resistive memory cell having a high resistance state and the leakage current through a turned-on resistive memory cell having a low resistance state.

The read operation may include a pre-charge step where each selected primary bit line and each selected complementary bit line are electrically biased at a bit line bias voltage, which is also referred to as a reference voltage V_REF, prior to a read output generation step. For each selected primary bit line, a corresponding complementary bit line connected to a same sense amplifier is also selected. In the example illustrated in FIGS. 5B and 5C, all primary bit lines and all complementary bit lines are simultaneously selected to provide sensing of data from a selected row of primary memory cells, such as primary memory cells C_i,k in which i is a fixed index and k is a running index that runs from 1 to N. During the pre-charge step, each selected primary bit line and each selected complementary bit line functions as an electrode of a respective capacitor that is charged to the reference voltage V_REF. Upon termination of the pre-charge step, the voltage source that applies the reference voltage V_REF is disconnected from each selected primary bit line and from each selected complementary bit line. At this step, each selected primary bit line and each selected complementary bit line become an electrically floating electrode of a respective capacitor.

However, the selected primary bit lines and the selected complementary bit lines are not perfectly electrically floating once the voltage source for the reference voltage V_REF is disconnected. For each selected primary bit line, the predominant leakage source is a selected resistive memory cell that is connected to the respective selected primary bit line. The access transistor of the selected resistive memory cell is turned on, and the leakage current between the respective selected primary bit line and the electrical ground is inversely proportional to the resistance of the resistive memory element that is connected to the access transistor. Further, for each selected complementary bit line, the predominant leakage source is a series connection of an access transistor and a reference resistor in the reference leakage circuit RLC that is connected to the respective selected complementary bit line. The access transistor in the series connection is turned on, and the leakage current between the respective selected complementary bit line and the electrical ground is inversely proportional to the resistance of the reference resistor that is connected to the access transistor.

For each pair of a selected primary bit line and a complementary bit line that is connected to the input nodes of a respective sense amplifier, the resistive state of the selected primary memory cell connected to the selected primary bit line may be sensed by generating output voltages from the respective sense amplifiers. In the operational mode illustrated in FIGS. 5B and 5C, N outputs from N sense amplifiers may be simultaneously generated, which represent data stored in the selected row of primary resistive memory cells (such as the primary resistive memory cells located in the i-th row of the primary memory array).

In some embodiments, not every sense amplifier in the resistive memory array may be used for sensing. FIGS. 5D and 5E illustrate a second type of read operation where only a single data bit stored in a selected resistive memory cell is read by activating a single sense amplifier. FIG. 5D illustrates a portion of the memory array MA, and FIG. 5E illustrates a portion of the reference array RA. In the illustrated example in FIGS. 5D and 5E, only the data stored in the i-th row j-th column primary memory cell C_i,j may be sensed by activating the i-th primary word line, the j-th primary bit line, and the j-th complementary bit line, by applying a leakage-current suppression voltage to all other word lines, and by electrically grounding all other bit lines and the source lines.

Generally, the second exemplary resistive memory device may be operated in the same manner as the first exemplary resistive memory device except that the memory array MA is used to store and read data and the reference array RA is not used to store or read data.

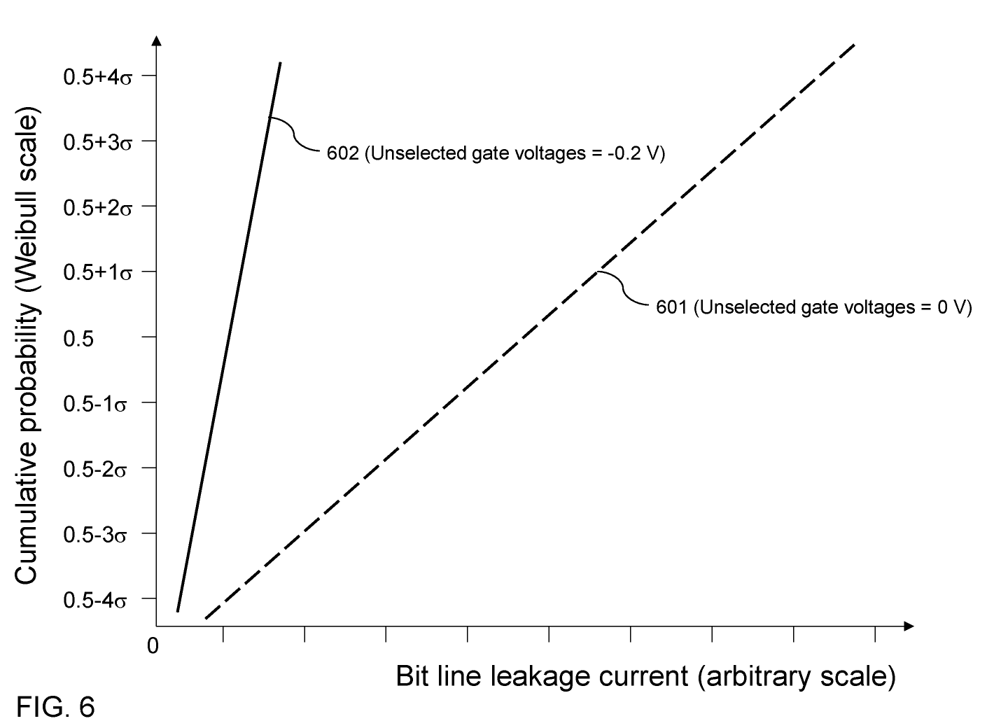

FIG. 6 shows the probability distribution of bit line leakage current for a first operational mode in which 0 V is applied to unselected word lines, and for a second operational mode in which -0.2 V is applied to the unselected word lines during a read operation on a resistive memory array. Curve 601 shows the probability distribution for the bit line leakage current in the first operational mode in which 0 V is applied to unselected word lines for a bit line connected to 1,024 resistive memory cells. Curve 602 shows the probability distribution for the bit line leakage current in the second operational mode in which -0.2 V is applied to unselected word lines for a bit line connected to 1,024 resistive memory cells. Application of a negative gate voltage to the access transistors not only reduces the mean leakage current, but reduces the values of low-probability high-end leakage current, and thus, increases the manufacturing yield of a resistive memory array device of the present disclosure.

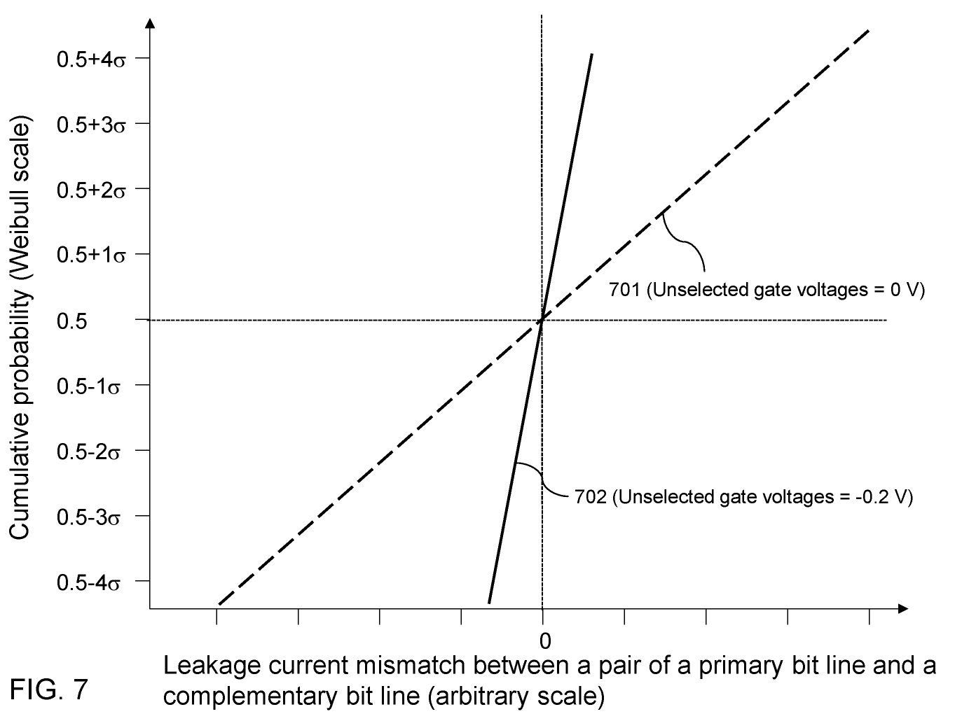

FIG. 7 shows the probability distribution of bit line leakage current mismatch between a pair of a primary bit line and a complementary bit line for a first operational mode in which 0 V is applied to unselected word lines, and for a second operational mode in which -0.2 V is applied to the unselected word lines during a read operation on a resistive memory array according to an embodiment of the present disclosure. Bit line leakage current mismatch refers to the difference between the bit line leakage current for a primary bit line when all access transistors in the primary memory array are turned off at least nominally and the bit line leakage current for a complementary bit line when all access transistors in the complementary memory array are turned off at least nominally. In this example, the primary bit line is connected to 1,024 primary resistive memory cells, and the complementary bit line is connected to 1,024 complementary resistive memory cells. Curve 701 shows the probability distribution for the bit line leakage current mismatch in the first operational mode in which 0 V is applied to all word lines in the primary memory array and in the complementary memory array. Curve 702 shows the probability distribution for the bit line leakage current mismatch in the first operational mode in which -0.2 V is applied to all word lines in the primary memory array and in the complementary memory array. Application of a negative gate voltage to the access transistors reduces the magnitudes of low-probability high-end leakage current, and thus, increases the manufacturing yield of a resistive memory array device of the present disclosure.

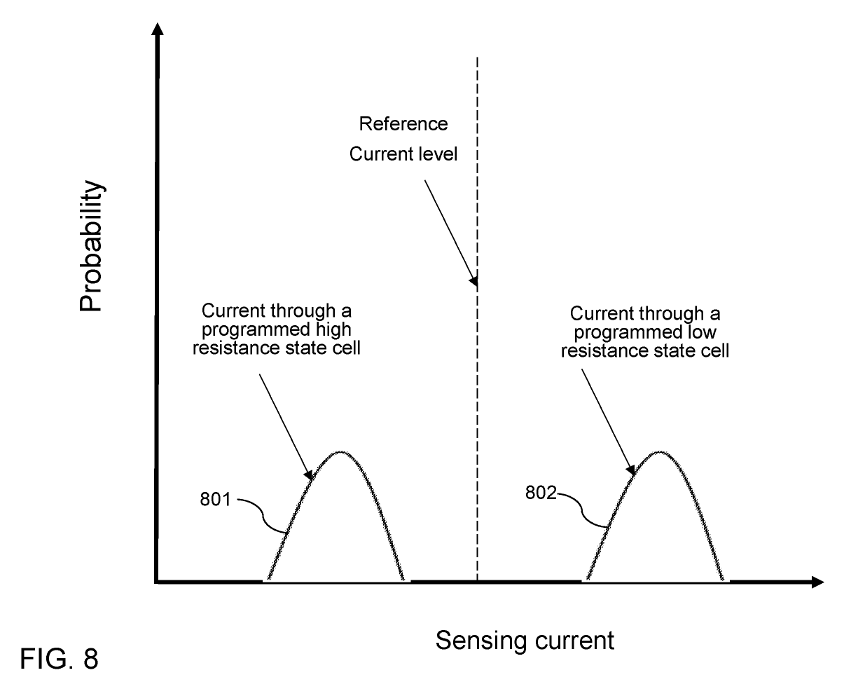

Referring to FIG. 8, the probability distribution for the electrical current through a bit line is illustrated for various circuit configurations. Curve 801 illustrates the probability distribution of the electrical current through a selected primary bit line for a high resistance state of a selected resistive memory cell. Curve 802 illustrates the probability distribution of the electrical current through a selected primary bit line for electrical current through a selected primary bit line for a low resistance state of the selected memory cell. Curve 803 illustrates the probability distribution of the electrical current through a selected complementary bit line according to an embodiment of the present disclosure. The reduction of the leakage current through a column of unselected resistive memory cells that are connected to the selected primary bit line reduces the standard deviation of the leakage currents for the selected primary bit line for the high resistance state of the selected resistive memory cell as illustrated by curve 801, and for the low resistance state of the selected resistive memory cell as illustrated by curve 802. Further, the reduction of the leakage current through a column of resistive memory cells that are connected to the selected complementary bit line reduces the standard deviation of the leakage currents for the complementary bit line during sensing as illustrated by curve 803. Thus, the overlap among the probability distributions of curves 801, 802, and 803 may be eliminated or minimized through use of the sensing scheme of the embodiments of the present disclosure.

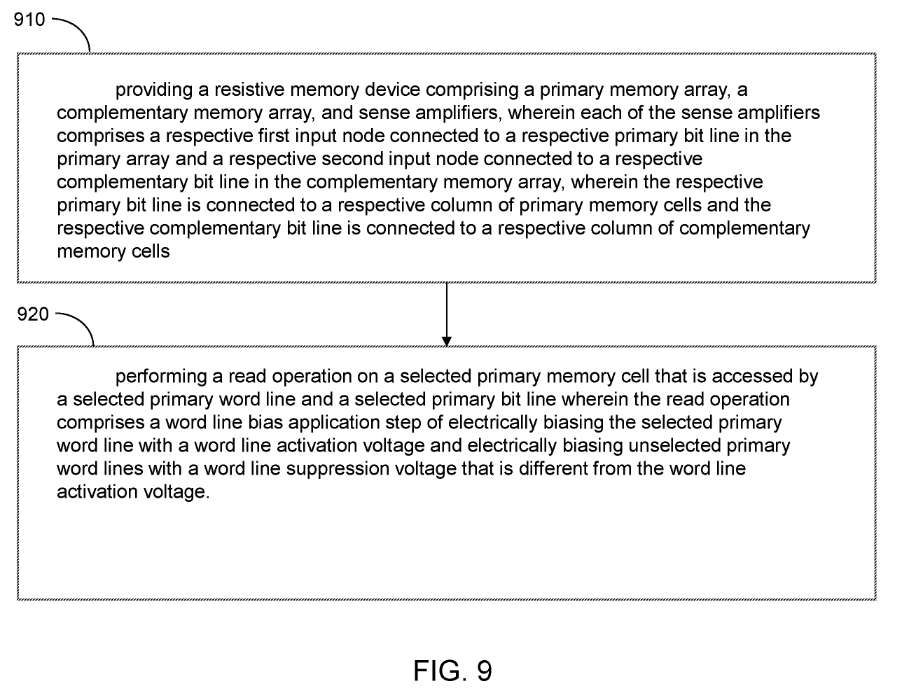

Referring to FIG. 9, a flow chart for a sequence of steps for a method of operating a resistive memory array is provided.

Referring step 910, a resistive memory device is provided, which comprises a primary memory array, a complementary memory array, and sense amplifiers. Each of the sense amplifiers comprises a respective first input node connected to a respective primary bit line in the primary array and a respective second input node connected to a respective complementary bit line in the complementary memory array. The respective primary bit line is connected to a respective column of primary memory cells and the respective complementary bit line is connected to a respective column of complementary memory cells.

Referring to step 920, a read operation may be performed on a selected primary memory cell that is accessed by a selected primary word line and a selected primary bit line. The read operation may be effected by performing a word line bias application step of electrically biasing the selected primary word line with a word line activation voltage and electrically biasing unselected primary word lines with a leakage-current suppression voltage that is different from the word line activation voltage. For example, the leakage-current suppression volatage may have an opposite polarity than the word line activation voltage. In an embodiment, the read operation may further include performing a read output generation step of sensing a resistive state of the selected primary memory cell by generating an output voltage from a selected sense amplifier that is connected to the selected primary bit line.

In an embodiment, the read operation may include a pre-charge step in which the selected primary bit line and a selected complementary bit line that is connected to the second input node of the selected sense amplifier are electrically biased at a bit line bias voltage prior to performing the read output generation step. In an embodiment, the resistive memory device may include a complementary reference leakage circuit that is attached to the complementary bit lines and configured to provide a reference leakage current to each of the complementary bit lines; and the method of operating a resistive memory array includes activating a reference leakage path within the complementary reference leakage circuit that is connected to the selected complementary bit line prior to performing the read output generation step. In an embodiment, the method of operating a resistive memory array may further include the steps of: storing a data bit in a selected complementary memory cell that is accessed by a selected complementary word line and a selected complementary bit line within the complementary memory array; and performing an additional read operation on the selected complementary memory cell by performing: an additional word line bias application step of electrically biasing the selected complementary word line with the word line activation voltage and electrically biasing unselected complementary word lines with the leakage-current suppression voltage, and an additional read output generation step of sensing a resistive state of the selected complementary memory cell by generating an output voltage from an additional selected sense amplifier that is connected to the selected complementary bit line. In an embodiment, the method of operating a resistive memory array may further include the steps of: electrically biasing all primary word lines in the primary memory array with the leakage-current suppression voltage while performing the additional read output generation step. In an embodiment, the respective primary resistive memory element comprises a conductive-filament-forming transition metal oxide material; and the method of operating a resistive memory array may further include the steps of: programming a primary resistive memory element of the selected primary memory cell into a target resistance state that is selected from a low resistance state in which conductive filaments are present within the primary resistive memory element and a high resistance state in which the primary resistive memory element is substantially free of the conductive filaments. In an embodiment, each of the primary memory cells in the primary memory array comprises a series connection of a respective primary resistive memory element and a respective primary access transistor having a respective primary gate electrode that is electrically biased by a respective one of primary word lines; and each of the primary access transistors comprises a respective source region that is electrically grounded during the word line bias application step. In an embodiment, each of the complementary memory cells in the complementary memory array comprises a series connection of a respective complementary resistive memory element and a respective complementary access transistor having a respective complementary gate electrode that is electrically biased by a respective one of complementary word lines; and the complementary access transistors and the primary access transistors have a same set of a nominal gate thickness, a nominal gate length, a nominal gate width, and a gate electrode material composition.

According to an aspect of the present disclosure, a resistive memory device may comprise a primary memory array, a complementary memory array, sense amplifiers, and a control circuit. In one embodiment, each of the sense amplifiers may comprise a respective first input node connected to a respective primary bit line in the primary array and a respective second input node connected to a respective complementary bit line in the complementary memory array. The respective primary bit line may be connected to a respective column of primary memory cells and the respective complementary bit line may be connected to a respective column of complementary memory cells. The control circuit may be configured to perform a read operation on a selected primary memory cell by electrically biasing a selected primary word line with a word line activation voltage and electrically biasing unselected primary word lines with a leakage-current suppression voltage that is different from the word line activation voltage. For example, the leakage-current suppression voltage may have an opposite polarity of the word line activation voltage.

In an embodiment, the control circuit may then sense a resistive state of the selected primary memory cell by generating an output voltage from a selected sense amplifier that is connected to the selected primary bit line.

In one embodiment, the control circuit may be configured to electrically bias at least one complementary word line in the complementary memory array with the leakage-current suppression voltage during the read operation. This may help to further reduce leakage currents in the complementary memory array.

The respective column of primary memory cells may comprise a respective set of M primary memory cells, and the respective column of complementary memory cells may comprise a respective set of M complementary memory cells, where M may be an integer in a range from 2 to 2¹⁶. This configuration may allow for a high-density memory array with a large number of memory cells per bit line.

In one embodiment, the resistive memory device may further comprise a pre-charge circuit configured to electrically bias the selected primary bit line and a selected complementary bit line at a bit line bias voltage prior to sensing the resistive state of the selected primary memory cell. This pre-charge step establishes a known initial voltage on the bit lines before sensing the resistive state of the selected memory cell.

The resistive memory device may also include a complementary reference leakage circuit attached to the complementary bit lines and configured to provide a reference leakage current to each of the complementary bit lines. In this embodiment, the control circuit may be configured to activate a reference leakage path within the complementary reference leakage circuit that is connected to the selected complementary bit line prior to sensing the resistive state of the selected primary memory cell.

In one embodiment, the primary memory cells in the primary memory array may comprise a series connection of a respective primary resistive memory element and a respective primary access transistor having a respective primary gate electrode that is electrically biased by a respective one of primary word lines. Each of the primary access transistors may comprise a respective source region that is electrically grounded during the read operation.

Similarly, in another embodiment, the complementary memory cells in the complementary memory array may comprise a series connection of a respective complementary resistive memory element and a respective complementary access transistor having a respective complementary gate electrode that is electrically biased by a respective one of complementary word lines. In some embodiments, the complementary access transistors and the primary access transistors may have a same set of a nominal gate thickness, a nominal gate length, a nominal gate width, and a gate electrode material composition.

In one embodiment, the primary resistive memory elements may comprise a conductive-filament-forming transition metal oxide material. The control circuit may be configured to program a primary resistive memory element of the selected primary memory cell into a target resistance state that is selected from a low resistance state in which conductive filaments are present within the primary resistive memory element and a high resistance state in which the primary resistive memory element is substantially free of the conductive filaments.

In some embodiments, the control circuit may be further configured to perform an additional read operation on a selected complementary memory cell. This additional read operation may include electrically biasing a selected complementary word line with the word line activation voltage and electrically biasing unselected complementary word lines with the leakage-current suppression voltage. The control circuit may then sense a resistive state of the selected complementary memory cell by generating an output voltage from an additional selected sense amplifier that is connected to a selected complementary bit line.

During this additional read operation, the control circuit may be configured to electrically bias all primary word lines in the primary memory array with the leakage-current suppression voltage while sensing the resistive state of the selected complementary memory cell. This configuration may allow for the complementary memory array to be used for data storage in addition to providing reference signals, potentially increasing the overall storage capacity of the device.

In summary, embodiments of the present disclosure provide resistive memory devices and methods for operating the same. The embodiments of the present disclosure reduce leakage currents and enhances sensing accuracy. The devices may include a primary memory array, a complementary memory array, and sense amplifiers configured to read data from selected memory cells. By applying a word line activation voltage to a selected word line and a leakage-current suppression voltage of opposite polarity to unselected word lines, the devices may reduce bit line leakage currents.

The application of a negative bias to unselected word lines suppresses RRAM bit line leakage during read operations, and increases the read window and sensing margin. Embodiments of the present disclosure may be especially effective in resistive memory arrays with long bit lines, where cumulative leakage from multiple unselected cells may impact sensing accuracy. Further, the reduction in leakage current may lead to improved manufacturing yield by mitigating the effects of low-probability, high-end leakage events. In addition, the flexibility to perform read operations on both primary and complementary memory arrays may increase the overall storage capacity and functionality of the device. These advantages may contribute to more reliable and efficient resistive memory devices suitable for use in various electronic applications.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of operating a resistive memory array, the method comprising:
providing a resistive memory device comprising a primary memory array, a complementary memory array, and sense amplifiers, wherein each of the sense amplifiers comprises a respective first input node connected to a respective primary bit line in the primary array and a respective second input node connected to a respective complementary bit line in the complementary memory array, wherein the respective primary bit line is connected to a respective column of primary memory cells and the respective complementary bit line is connected to a respective column of complementary memory cells; and
performing a read operation on a selected primary memory cell that is accessed by a selected primary word line and a selected primary bit line, wherein the read operation comprises a word line bias application step of electrically biasing the selected primary word line with a word line activation voltage and electrically biasing unselected primary word lines with a leakage-current suppression voltage that is different from the word line activation voltage.

2. The method of claim 1, wherein the read operation comprises a read output generation step of sensing a resistive state of the selected primary memory cell by generating an output voltage from a selected sense amplifier that is connected to the selected primary bit line.

3. The method of claim 2, further comprising electrically biasing at least one complementary word line in the complementary memory array with the leakage-current suppression voltage while performing the read output generation step.

4. The method of claim 2, wherein the read operation comprises a pre-charge step in which the selected primary bit line and a selected complementary bit line that is connected to the second input node of the selected sense amplifier are electrically biased at a bit line bias voltage prior to performing the read output generation step.

5. The method of claim 4, wherein:
the resistive memory device comprises a complementary reference leakage circuit that is attached to the complementary bit lines and configured to provide a reference leakage current to each of the complementary bit lines; and
the method comprises activating a reference leakage path within the complementary reference leakage circuit that is connected to the selected complementary bit line prior to performing the read output generation step.

6. The method of claim 2, further comprising:
storing a data bit in a selected complementary memory cell that is accessed by a selected complementary word line and a selected complementary bit line within the complementary memory array; and
performing an additional read operation on the selected complementary memory cell by performing:
an additional word line bias application step of electrically biasing the selected complementary word line with the word line activation voltage and electrically biasing unselected complementary word lines with the leakage-current suppression voltage, and
an additional read output generation step of sensing a resistive state of the selected complementary memory cell by generating an output voltage from an additional selected sense amplifier that is connected to the selected complementary bit line.

7. The method of claim 6, further comprising electrically biasing all primary word lines in the primary memory array with the leakage-current suppression voltage while performing the additional read output generation step.

8. The method of claim 1, wherein:
the respective primary resistive memory element comprises a conductive-filament-forming transition metal oxide material; and
the method comprises programming a primary resistive memory element of the selected primary memory cell into a target resistance state that is selected from a low resistance state in which conductive filaments are present within the primary resistive memory element and a high resistance state in which the primary resistive memory element is substantially free of the conductive filaments.

9. The method of claim 1, wherein:
each of the primary memory cells in the primary memory array comprises a series connection of a respective primary resistive memory element and a respective primary access transistor having a respective primary gate electrode that is electrically biased by a respective one of primary word lines; and
each of the primary access transistors comprises a respective source region that is electrically grounded during the word line bias application step.

10. The method of claim 9, wherein:
each of the complementary memory cells in the complementary memory array comprises a series connection of a respective complementary resistive memory element and a respective complementary access transistor having a respective complementary gate electrode that is electrically biased by a respective one of complementary word lines; and
the complementary access transistors and the primary access transistors have a same set of a nominal gate thickness, a nominal gate length, a nominal gate width, and a gate electrode material composition.

11. A resistive memory device comprising:
a primary memory array;
a complementary memory array;
sense amplifiers, wherein each of the sense amplifiers comprises a respective first input node connected to a respective primary bit line in the primary array and a respective second input node connected to a respective complementary bit line in the complementary memory array, and wherein the respective primary bit line is connected to a respective column of primary memory cells and the respective complementary bit line is connected to a respective column of complementary memory cells; and
a control circuit configured to perform a read operation on a selected primary memory cell, wherein the read operation comprises a word line bias application step which electrically biases a selected primary word line with a word line activation voltage and electrically biases unselected primary word lines with a leakage-current suppression voltage that is different from the word line activation voltage.

12. The resistive memory device of claim 1, wherein the control circuit is configured to perform a read output generation step which senses a resistive state of the selected primary memory cell by generating an output voltage from a selected sense amplifier that is connected to the selected primary bit line.

13. The resistive memory device of claim 11, wherein the control circuit is configured to electrically bias at least one complementary word line in the complementary memory array with the leakage-current suppression voltage during the read operation.

14. The resistive memory device of claim 11, further comprising a pre-charge circuit configured to electrically bias the selected primary bit line and a selected complementary bit line at a bit line bias voltage prior to sensing the resistive state of the selected primary memory cell.

15. The resistive memory device of claim 14, further comprising a complementary reference leakage circuit attached to the complementary bit lines and configured to provide a reference leakage current to each of the complementary bit lines, wherein the control circuit is configured to activate a reference leakage path within the complementary reference leakage circuit that is connected to the selected complementary bit line prior to sensing the resistive state of the selected primary memory cell.

16. The resistive memory device of claim 11, wherein:
each of the primary memory cells in the primary memory array comprises a series connection of a respective primary resistive memory element and a respective primary access transistor having a respective primary gate electrode that is electrically biased by a respective one of primary word lines; and
each of the primary access transistors comprises a respective source region that is electrically grounded during the read operation.

17. The resistive memory device of claim 16, wherein:
each of the complementary memory cells in the complementary memory array comprises a series connection of a respective complementary resistive memory element and a respective complementary access transistor having a respective complementary gate electrode that is electrically biased by a respective one of complementary word lines; and
the complementary access transistors and the primary access transistors have a same set of a nominal gate thickness, a nominal gate length, a nominal gate width, and a gate electrode material composition.

18. A resistive memory device comprising:
a primary memory array;
a complementary memory array;
sense amplifiers, wherein the sense amplifiers comprises a respective first input node connected to a respective primary bit line in the primary array and a respective second input node connected to a respective complementary bit line in the complementary memory array, and wherein the respective primary bit line is connected to a respective column of primary memory cells and the respective complementary bit line is connected to a respective column of complementary memory cells; and
a control circuit configured to perform a first read operation on a selected primary memory cell by:
electrically biasing a selected primary word line with a word line activation voltage and electrically biasing unselected primary word lines with a leakage-current suppression voltage, and
sensing a resistive state of the selected primary memory cell by generating an output voltage from a selected sense amplifier that is connected to the selected primary bit line,
wherein the control circuit configured to perform a second read operation on a selected complementary memory cell by:
electrically biasing a selected complementary word line with the word line activation voltage and electrically biasing unselected complementary word lines with the leakage-current suppression voltage, and
sensing a resistive state of the selected complementary memory cell by generating an output voltage from an additional selected sense amplifier that is connected to a selected complementary bit line.

19. The resistive memory device of claim 18, wherein the control circuit is configured to:
electrically bias all complementary word lines in the complementary memory array with the leakage-current suppression voltage while sensing the resistive state of the selected primary memory cell; and
electrically bias all primary word lines in the primary memory array with the leakage-current suppression voltage while sensing the resistive state of the selected complementary memory cell.

20. The resistive memory device of claim 18, wherein:
the primary memory cells comprise primary resistive memory elements that include a conductive-filament-forming transition metal oxide material; and
the control circuit is configured to program a primary resistive memory element of the selected primary memory cell into a target resistance state that is selected from a low resistance state in which conductive filaments are present within the primary resistive memory element and a high resistance state in which the primary resistive memory element is substantially free of the conductive filaments.
